(19) United States
(12) Patent Application Publication
(10) Pub. No.: US 2026/0062788 A1
(43) Pub. Date: Mar. 5, 2026

(54) MASK STAGE, DEPOSITION APPARATUS INCLUDING THE MASK STAGE, AND ELECTRONIC DEVICE MANUFACTURED BY USING THE DEPOSITION APPARATUS

(71) Applicant: Samsung Display Co., LTD., Yongin-si (KR)

(72) Inventor: Sung Woon KIM, Yongin-si (KR)

(21) Appl. No.: 19/191,238

(22) Filed: Apr. 28, 2025

(30) Foreign Application Priority Data
Aug. 29, 2024 (KR) 10-2024-0116505

(51) Int. Cl. C23C 14/04; H01L 21/683; H10K 59/12; H10K 71/16

(52) U.S. Cl. CPC C23C 14/042; H10K 59/1201; H10K 71/166

(57) ABSTRACT

Provided are a mask stage, a deposition apparatus including the mask stage, and an electronic device manufactured by using the deposition apparatus. The mask stage includes a lattice support which supports a deposition mask and comprises a plurality of opening regions and at least one chuck mount region, a first electrostatic chuck which surrounds the lattice support, supports an edge region of the deposition mask, and holds the edge region of the deposition mask using a first electrostatic force, and at least one second electrostatic chuck which is disposed on the at least one chuck mount region, supports a portion of the deposition mask, and holds the portion of the deposition mask using a second electrostatic force.

This application claims priority to Korean Patent Application No. 10-2024-0116505, filed on Aug. 29, 2024, and all the benefits accruing therefrom under 35 U.S.C. § 119, the content of which in its entirety is herein incorporated by reference.

### BACKGROUND

### 1. Field

The present disclosure relates to a mask stage, a deposition apparatus including the mask stage, and an electronic device manufactured by using the deposition apparatus.

### 2. Description of the Related Art

Wearable devices in which a focus is formed at a distance close to user's eyes have been developed in the form of glasses or a helmet. For example, the wearable device may be a head mounted display (HMD) device or AR glasses. The wearable device may provide an augmented reality (hereinafter, referred to as “AR”) screen or a virtual reality (hereinafter, referred to as “VR”) screen to a user.

In the case of wearable devices such as, for example, HMD devices or AR glasses, providing a high-resolution image, e.g., an image with a resolution of about 3000 PPI (pixels per inch) or higher, may enable users to use the wearable devices for a long time without symptoms of dizziness. To this end, an organic light emitting diode on silicon (OLEDoS) technology used for high-resolution small organic light emitting display devices has attracted attention. The OLEDoS is a technology in which an organic light emitting diodes (OLED) are disposed on a semiconductor substrate on which complementary metal oxide semiconductor (CMOS) elements are disposed.

Some approaches for manufacturing a display panel with a high resolution of about 3000 PPI or higher may use a high-resolution deposition mask. For example, the deposition mask may be manufactured by forming a membrane having a plurality of pixel openings on a substrate such as, for example, a silicon wafer, and partially removing the substrate to form cell openings that expose the pixel openings.

A deposition mask may be used in a deposition process for forming light emitting layers of sub-pixels on a backplane substrate. While the deposition process is being performed, the backplane substrate may be disposed on the deposition mask, and a deposition source for providing a vapor deposition material may be disposed under the deposition mask. However, if warpage occurs during the manufacturing process of the deposition mask, parallelism between the backplane substrate and the deposition mask may deteriorate, such that the pixel position accuracy (PPA) of the light emitting layers formed on the backplane substrate may deteriorate, and a color mixing phenomenon may occur between the sub-pixels.

### SUMMARY

Aspects and features of embodiments of the present disclosure provide a mask stage capable of reducing warpage of a deposition mask, a deposition apparatus including the mask stage, and an electronic device manufactured by using the deposition apparatus.

However, embodiments of the present disclosure are not limited to those set forth herein. The above and other embodiments of the present disclosure will become more apparent to one of ordinary skill in the art to which the present disclosure pertains by referencing the detailed description of the present disclosure given below.

In accordance with an aspect of the present disclosure, a mask stage may include a lattice support which supports a deposition mask and includes a plurality of opening regions and at least one chuck mount region, a first electrostatic chuck which surrounds the lattice support, supports an edge region of the deposition mask, and holds the edge region of the deposition mask using a first electrostatic force, and at least one second electrostatic chuck which is disposed on the at least one chuck mount region, supports a portion of the deposition mask, and holds the portion of the deposition mask using a second electrostatic force.

In accordance with some embodiments of the present disclosure, the deposition mask may include mask cell regions in which pixel openings are formed and a closed cell region in which pixel openings are not formed, and the at least one second electrostatic chuck may support the closed cell region and hold the closed cell region using the second electrostatic force.

In accordance with some embodiments of the present disclosure, the at least one chuck mount region may have a recess into which the at least one second electrostatic chuck is inserted.

In accordance with some embodiments of the present disclosure, the lattice support may further include a grid region disposed between the plurality of opening regions and the at least one chuck mount region, and a top surface of the grid region and a top surface of the at least one second electrostatic chuck may be disposed at the same height.

In accordance with some embodiments of the present disclosure, the mask stage may further include a base plate disposed under the lattice support and having an opening exposing the lattice support, and a support ring disposed between the lattice support and the base plate.

In accordance with some embodiments of the present disclosure, the first electrostatic chuck may include a first electrostatic electrode and a second electrostatic electrode. The first electrostatic electrode may include a first main electrode having a ring shape and a plurality of first branch electrodes extending from the first main electrode toward the second electrostatic electrode, and the second electrostatic electrode may include a second main electrode having a ring shape and a plurality of second branch electrodes extending from the second main electrode toward the first electrostatic electrode.

In accordance with some embodiments of the present disclosure, the mask stage may further include a first connector connecting the first electrostatic electrode to a power supply unit, and a second connector connecting the second electrostatic electrode to the power supply unit. The first electrostatic chuck may further include a first connection line connecting the first electrostatic electrode and the first connector, and a second connection line connecting the second electrostatic electrode and the second connector.

In accordance with some embodiments of the present disclosure, the at least one second electrostatic chuck may include a third electrostatic electrode and a fourth electrostatic electrode. The third electrostatic electrode may include a third main electrode extending in a first direction and a plurality of third branch electrodes extending from the third main electrode toward the fourth electrostatic electrode, and the fourth electrostatic electrode may include a fourth main electrode extending parallel to the third main electrode and a plurality of fourth branch electrodes extending from the fourth main electrode toward the third electrostatic electrode.

In accordance with some embodiments of the present disclosure, the first connector may connect the third electrostatic electrode to the power supply unit, and the second connector may connect the fourth electrostatic electrode to the power supply unit. In such case, the mask stage may further include a third connection line disposed on the lattice support and connecting the third electrostatic electrode and the first connector, and a fourth connection line disposed on the lattice support and connecting the fourth electrostatic electrode and the second connector.

In accordance with some embodiments of the present disclosure, the lattice support may include a plurality of chuck mount regions, and a plurality of second electrostatic chucks may be respectively disposed on the plurality of chuck mount regions.

In accordance with another aspect of the present disclosure, a deposition apparatus may include a deposition source providing a deposition material onto a substrate, a mask stage which is disposed above the deposition source and supports a deposition mask, and a substrate chuck which is disposed above the mask stage and supports the substrate such that the substrate faces the deposition mask. The mask stage may include a lattice support which supports the deposition mask and includes a plurality of opening regions and at least one chuck mount region, a first electrostatic chuck which surrounds the lattice support, supports an edge region of the deposition mask, and holds the edge region of the deposition mask using a first electrostatic force, and at least one second electrostatic chuck which is disposed on the at least one chuck mount region, supports a portion of the deposition mask, and holds the portion of the deposition mask using a second electrostatic force.

In accordance with still another aspect of the present disclosure, an electronic device may include a substrate and a plurality of light emitting material layers formed on the substrate by using a deposition apparatus. The deposition apparatus may include a deposition source providing a deposition material onto a substrate, a mask stage which is disposed above the deposition source and supports a deposition mask, and a substrate chuck which is disposed above the mask stage and supports the substrate such that the substrate faces the deposition mask. The mask stage may include a lattice support which supports the deposition mask and includes a plurality of opening regions and at least one chuck mount region, a first electrostatic chuck which surrounds the lattice support, supports an edge region of the deposition mask, and holds the edge region of the deposition mask using a first electrostatic force, and at least one second electrostatic chuck which is disposed on the at least one chuck mount region, supports a portion of the deposition mask, and holds the portion of the deposition mask using a second electrostatic force.

According to embodiments of the present disclosure described herein, when a deposition mask is placed on a mask stage, an edge region of the deposition mask may be held by a first electrostatic chuck, and a closed cell region of the deposition mask may be held by a second electrostatic chuck. Therefore, the warpage of the deposition mask may be reduced.

Other features and embodiments may be apparent from the following detailed description and the drawings.

### BRIEF DESCRIPTION OF THE DRAWINGS

The above and other aspects and features of the present disclosure will become more apparent by describing in detail example embodiments thereof with reference to the attached drawings, in which:

FIG. 1 is a block diagram of an electronic device according to an embodiment of the present disclosure;

FIG. 2 is a schematic diagram of an electronic device according to various embodiments of the present disclosure;

FIG. 3 is an exploded perspective view illustrating a display device according to an embodiment of the present disclosure;

FIG. 4 is a block diagram illustrating the display device illustrated in FIG. 3;

FIG. 5 is an equivalent circuit diagram illustrating an example of a first sub-pixel illustrated in FIG. 4;

FIG. 6 is a schematic plan view illustrating an example of a display panel illustrated in FIG. 3;

FIG. 7 is a schematic enlarged plan view illustrating an example of a display area illustrated in FIG. 6;

FIG. 8 is a schematic enlarged plan view illustrating another example of the display area illustrated in FIG. 6;

FIG. 9 is a schematic cross-sectional view illustrating an example of the display panel taken along line I1-I1′ illustrated in FIG. 7;

FIG. 10 is a schematic cross-sectional view illustrating another example of the display panel taken along line I1-I1′ illustrated in FIG. 7;

FIG. 11 is a schematic perspective view illustrating an example of a head mounted display;

FIG. 12 is a schematic exploded perspective view illustrating the head mounted display illustrated in FIG. 11;

FIG. 13 is a schematic perspective view illustrating another example of the head mounted display;

FIG. 14 is a schematic diagram illustrating a mask stage and a deposition apparatus including the same according to an embodiment of the present disclosure;

FIG. 15 is a schematic bottom view illustrating an example of a backplane substrate illustrated in FIG. 14;

FIG. 16 is a schematic plan view illustrating an example of a deposition mask illustrated in FIG. 14;

FIG. 17 is a schematic enlarged plan view illustrating mask cell regions and a closed cell region illustrated in FIG. 16;

FIG. 18 is a schematic enlarged cross-sectional view taken along line I2-I2′ illustrated in FIG. 17;

FIG. 19 is a schematic plan view illustrating the mask stage illustrated in FIG. 14;

FIG. 20 is a schematic cross-sectional view illustrating the mask stage illustrated in FIG. 19;

FIG. 21 is a schematic plan view illustrating a first electrostatic chuck illustrated in FIG. 19;

FIG. 22 is a schematic enlarged cross-sectional view illustrating a first connector and a second connector illustrated in FIG. 19;

FIG. 23 is a block diagram illustrating the first connector and the second connector illustrated in FIG. 19;

FIG. 24 is a schematic enlarged plan view illustrating a second electrostatic chuck illustrated in FIG. 19;

FIG. 25 is a schematic enlarged cross-sectional view taken along line I3-I3′ illustrated in FIG. 24;

FIG. 26 is a schematic bottom view illustrating another example of the backplane substrate illustrated in FIG. 15;

FIG. 27 is a schematic plan view illustrating another example of the deposition mask illustrated in FIG. 16; and

FIG. 28 is a schematic plan view illustrating another example of the mask stage illustrated in FIG. 19.

### DETAILED DESCRIPTION

The invention will now be described more fully hereinafter with reference to the accompanying drawings, in which various embodiments of the present disclosure are illustrated. Aspects supported by the present disclosure may, however, be embodied in different forms and should not be construed as limited to the embodiments set forth herein. Rather, the example embodiments are provided such that this disclosure will be thorough and complete, and will fully convey the scope of example aspects of the present disclosure to those skilled in the art.

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” and the like may be used herein to describe various elements, these elements should not be limited by these terms. These terms are used to distinguish one element from another element. For instance, a first element discussed below could be termed a second element without departing from the teachings of the invention. Similarly, the second element could also be termed the first element.

The terminology used herein is for the purpose of describing particular embodiments and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as, for example, “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Features of each of various embodiments of the disclosure may be partially or entirely combined with each other and may technically variously interwork with each other, and respective embodiments may be implemented independently of each other or may be implemented together in association with each other.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments will be described in detail with reference to the accompanying drawings.

The display device according to an embodiment of the present disclosure can be applied to various electronic devices. The electronic device according to embodiments of the present disclosure includes the display device described herein, and may further include modules or devices having additional functions in addition to the display device.

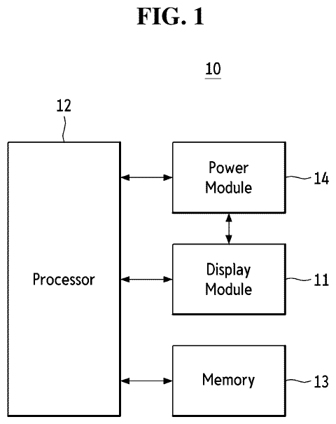

FIG. 1 is a block diagram of an electronic device according to an embodiment of the present disclosure.

Referring to FIG. 1, the electronic device 10 according to an embodiment of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information for the operation of the processor 12 or the display module 11. In an example in which the processor 12 executes an application stored in the memory 13, an image data signal and/or an input control signal is transmitted to the display module 11, and the display module 11 can process the received signal and output image information through a display screen.

The power module 14 may include a power supply module such as, for example, a power adapter or a battery, and a power conversion module that converts the power supplied by the power supply module to generate power for the operation of the electronic device 10.

At least one of the components of the electronic device 10 according to embodiments of the present disclosure may be included in the display device 20 according to the embodiments of the present disclosure. In some aspects, some modules of the individual modules functionally included in one module may be included in the display device 20, and other modules may be provided separately from the display device 10. For example, the display device 20 may include the display module 11, and the processor 12, the memory 13, and the power module 14 may be provided in the form of other devices within the electronic device 10 other than the display device 20.

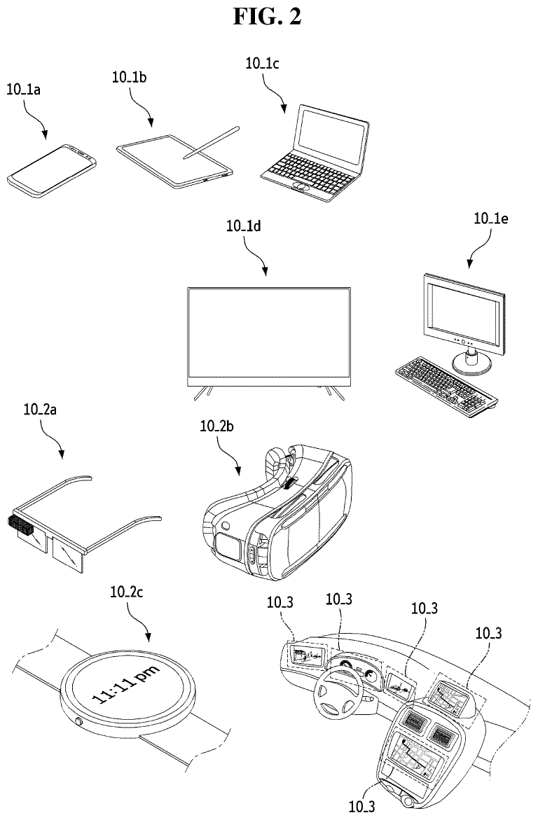

FIG. 2 is a schematic diagram of an electronic device according to various embodiments of the present disclosure.

Referring to FIG. 2, various electronic devices to which display devices 20 according to embodiments of the present disclosure are applied may include not only image display electronic devices such as, for example, a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as, for example, a CID (Center Information Display) and a room mirror display arranged on a dashboard, center fascia, and dashboard of an automobile.

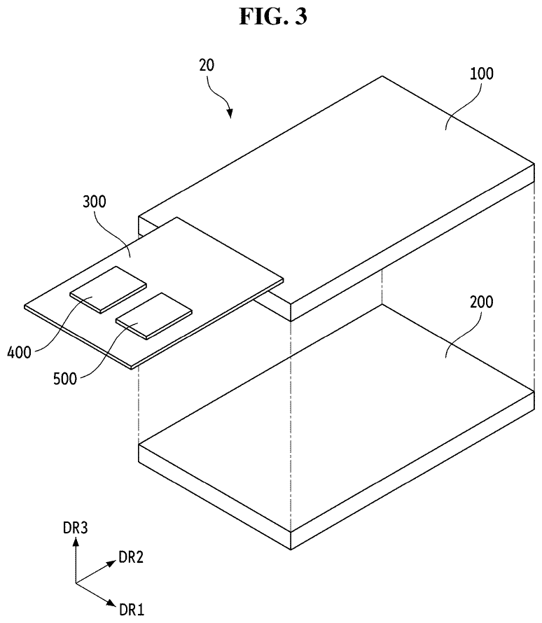

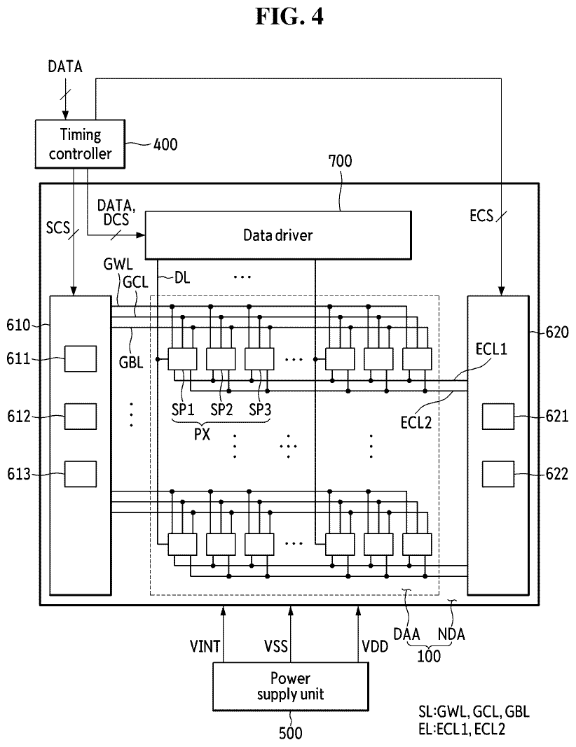

FIG. 3 is an exploded perspective view illustrating a display device according to an embodiment of the present disclosure. FIG. 4 is a block diagram illustrating the display device illustrated in FIG. 3.

Referring to FIGS. 3 and 4, a display device 20 according to an embodiment may be a device displaying a moving image or a still image. A display device 20 according to an embodiment may be used as the electronic device 10 or the display module 11 of the electronic device 10. For example, the display device 20 according to an embodiment may be applied to portable electronic devices 10 such as, for example, a mobile phone, a smartphone, a tablet personal computer, a mobile communication terminal, an electronic organizer, an electronic book, a portable multimedia player (PMP), a navigation system, an ultra mobile PC (UMPC), and the like. The display device 20 according to an embodiment may be applied as a display module 11 of electronic devices 10 such as, for example, a television, a laptop, a monitor, a billboard, or an Internet-of-Things (IoT) terminal, and the like. The display device 20 according to an embodiment may be applied to electronic devices 10 such as, for example, a smart watch, a watch phone, a head mounted display (HMD) for implementing virtual reality and augmented reality, and the like.

The display device 20 according to an embodiment may include a display panel 100, a heat dissipation layer 200, a circuit board 300, a timing control circuit 400, and a power supply circuit 500.

The display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a predetermined curvature. The planar shape of the display panel 100 is not limited to a quadrilateral shape, and may be a shape similar to another polygonal shape, a circular shape, or an elliptical shape. The planar shape of the display device 20 may conform to the planar shape of the display panel 100, but embodiments of the present disclosure are not limited thereto.

The display panel 100 may include a plurality of pixels PX, a plurality of scan lines SL, a plurality of emission control lines EL, a plurality of data lines DL, a scan driver 610, an emission driver 620, and a data driver 700. The display panel 100 may be divided into a display area DAA displaying an image and a non-display area NDA not displaying an image as illustrated in FIG. 4.

The plurality of pixels PX may be disposed in the display area DAA. The plurality of pixels PX may be arranged in a matrix form along the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

The plurality of scan lines SL may include a plurality of write scan lines GWL, a plurality of control scan lines GCL, and a plurality of bias scan lines GBL. The plurality of emission control lines EL include a plurality of first emission control lines ECL1 and a plurality of second emission control lines ECL2.

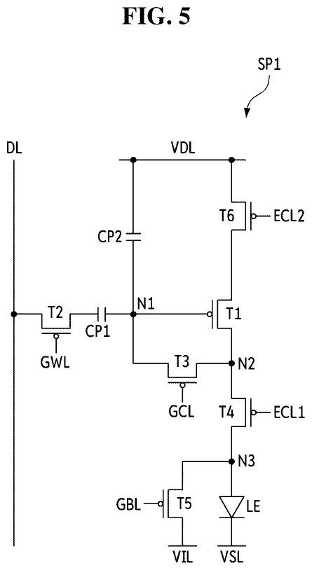

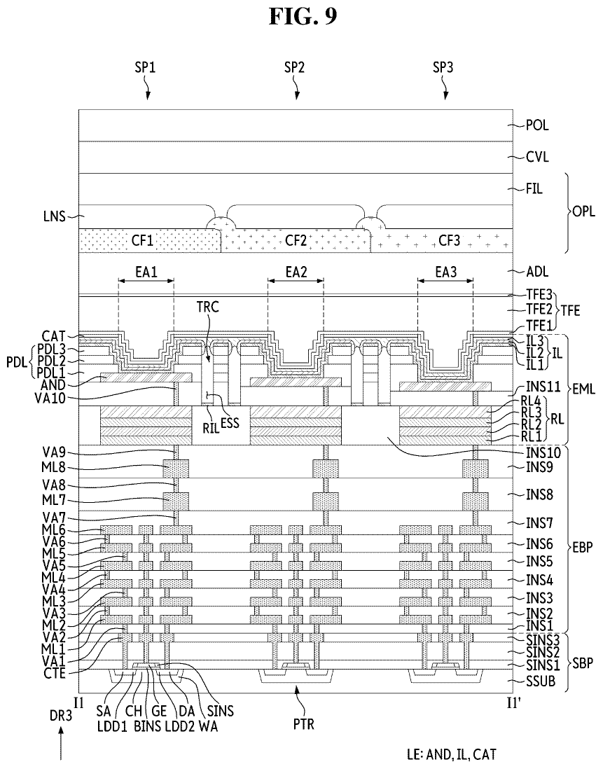

The plurality of pixels PX may include a plurality of sub-pixels SP1, SP2, and SP3. The plurality of sub-pixels SP1, SP2, and SP3 may include a plurality of pixel transistors as illustrated in FIG. 5, and the plurality of pixel transistors may be formed by a semiconductor process and disposed on a semiconductor substrate SSUB (see FIG. 9). For example, the plurality of pixel transistors of the data driver 700 may be formed of complementary metal oxide semiconductor (CMOS), but embodiments of the present disclosure are not limited thereto.

Each of the plurality of sub-pixels SP1, SP2, and SP3 may be connected to one write scan line GWL, one control scan line GCL, one bias scan line GBL, one first emission control line ECL1, one second emission control line ECL2, and one data line DL. Each of the plurality of sub-pixels SP1, SP2, and SP3 may receive a data voltage of the data line DL in response to a write scan signal of the write scan line GWL, and emit light from the light emitting element according to the data voltage.

The scan driver 610, the emission driver 620, and the data driver 700 may be disposed in the non-display area NDA.

The scan driver 610 includes a plurality of scan transistors, and the emission driver 620 includes a plurality of light emitting transistors. The plurality of scan transistors and the plurality of light emitting transistors may be formed on the semiconductor substrate SSUB (see FIG. 9) through a semiconductor process. For example, the plurality of scan transistors and the plurality of light emitting transistors may be formed of CMOS, but embodiments of the present disclosure are not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to the bias scan lines GBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines ECL1. The second emission control driver 622 may generate second emission control signals according to the emission timing control signal ECS and sequentially output them to the second emission control lines ECL2.

The data driver 700 may include a plurality of data transistors, and the plurality of data transistors may be formed on the semiconductor substrate SSUB (see FIG. 9) through a semiconductor process. For example, the plurality of data transistors may be formed of CMOS, but embodiments of the present disclosure are not limited thereto.

The data driver 700 may receive digital video data DATA and a data timing control signal DCS from the timing control circuit 400. The data driver 700 converts the digital video data DATA into analog data voltages according to the data timing control signal DCS and outputs the analog data voltages to the data lines DL. In this case, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be disposed on one surface of the display panel 100, for example, on the rear surface of the display panel 100. The heat dissipation layer 200 serves to dissipate heat generated from the display panel 100. The heat dissipation layer 200 may include a metal layer having high thermal conductivity, such as, for example, graphite, silver (Ag), copper (Cu), or aluminum (AI).

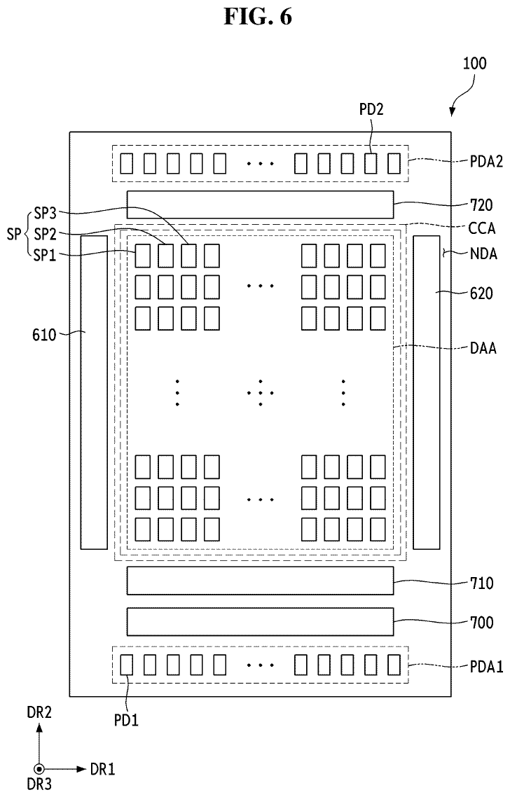

The circuit board 300 may be electrically connected to a plurality of first pads PD1 (see FIG. 6) of a first pad portion PDA1 (see FIG. 6) of the display panel 100 by using a conductive adhesive member such as, for example, an anisotropic conductive film. The circuit board 300 may be a flexible printed circuit board with a flexible material, or a flexible film. Although the circuit board 300 is illustrated in FIG. 3 as being unfolded, the circuit board 300 may be bent. In this case, one end of the circuit board 300 may be disposed on the rear surface of the display panel 100 and/or the rear surface of the heat dissipation layer 200. The other end of the circuit board 300 may be connected to the plurality of first pads PD1 (see FIG. 6) of the first pad portion PDA1 (see FIG. 6) of the display panel 100 by using a conductive adhesive member. One end of the circuit board 300 may be an opposite end of the other end of the circuit board 300.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply circuit 500 may generate a plurality of panel driving voltages according to a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 5.

Each of the timing control circuit 400 and the power supply circuit 500 may be formed as an integrated circuit (IC) and attached to one surface of the circuit board 300. In this case, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

Alternatively, each of the timing control circuit 400 and the power supply circuit 500 may be disposed in the non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. The plurality of timing transistors and the plurality of power transistors may be formed on the semiconductor substrate SSUB (see FIG. 9) through a semiconductor process. For example, the plurality of timing transistors and the plurality of power transistors may be formed of CMOS, but embodiments of the present disclosure are not limited thereto. Each of the timing control circuit 400 and the power supply circuit 500 may be disposed between the data driver 700 and the first pad portion PDA1 (see FIG. 6).

FIG. 5 is an equivalent circuit diagram illustrating an example of a first sub-pixel illustrated in FIG. 4.

Referring to FIG. 5, the first sub-pixel SP1 may be connected to the write scan line GWL, the control scan line GCL, the bias scan line GBL, the first emission control line ECL1, the second emission control line ECL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied.

The first sub-pixel SP1 may include a plurality of transistors T1 to T6, a light emitting element LE, a first capacitor CP1, and a second capacitor CP2.

The light emitting element LE emits light in response to a driving current flowing through the channel of the first transistor T1. The emission amount of the light emitting element LE may be proportional to the driving current. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer disposed between the first electrode and the second electrode, but embodiments of the present disclosure are not limited thereto. For example, the light emitting element LE may be an inorganic light emitting element including a first electrode, a second electrode, and an inorganic semiconductor disposed between the first electrode and the second electrode, in which case the light emitting element LE may be a micro light emitting diode.

The first transistor T1 may be a driving transistor that controls a source-drain current (hereinafter referred to as “driving current”) flowing between the source electrode and the drain electrode of the first transistor T1 according to a voltage applied to the gate electrode of the first transistor T1.

A second transistor T2 may be disposed between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1.

A third transistor T3 may be disposed between the first node N1 and the second node N2. The third transistor T3 is turned on by the control scan signal of the control scan line GCL to connect the first node N1 to the second node N2. For this reason, when the gate electrode and the source electrode of the first transistor T1 are connected, the first transistor T1 may operate like a diode.

The fourth transistor T4 may be connected between the second node N2 and a third node N3. The fourth transistor T4 is turned on by the first emission control signal of the first emission control line ECL1 to connect the second node N2 to the third node N3. Accordingly, the driving current of the first transistor T1 may be supplied to the light emitting element LE. A fifth transistor T5 may be disposed between the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light emitting element LE.

The sixth transistor T6 may be disposed between the source electrode of the first transistor T1 and the second driving voltage line VDL. The sixth transistor T6 is turned on by the second emission control signal of the second emission control line ECL2 to connect the source electrode of the first transistor T1 to the second driving voltage line VDL. Accordingly, the second driving voltage VDD of the second driving voltage line VDL may be applied to the source electrode of the first transistor T1.

The first capacitor CP1 is formed between the first node N1 and the drain electrode of the second transistor T2. The second capacitor CP2 is formed between the gate electrode of the first transistor T1 and the second driving voltage line VDL.

Each of the first to sixth transistors T1 to T6 may be a metal-oxide-semiconductor field effect transistor (MOSFET). For example, each of the first to sixth transistors T1 to T6 may be a P-type MOSFET, but embodiments of the present disclosure are not limited thereto. Each of the first to sixth transistors T1 to T6 may be an N-type MOSFET. Alternatively, some of the first to sixth transistors T1 to T6 may be P-type MOSFETs, and each of the remaining transistors may be an N-type MOSFET.

Although it is illustrated in FIG. 5 that the first sub-pixel SP1 includes six transistors T1 to T6 and two capacitors C1 and C2, it should be noted that the equivalent circuit diagram of the first sub-pixel SP1 is not limited to that illustrated in FIG. 5. For example, the number of transistors and the number of capacitors of the first sub-pixel SP1 are not limited to those illustrated in FIG. 5.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 5. Therefore, the description of the equivalent circuit diagram of the second sub-pixel SP2 and the equivalent circuit diagram of the third sub-pixel SP3 is not repeated in the present disclosure.

FIG. 6 is a schematic plan view illustrating an example of a display panel illustrated in FIG. 3.

Referring to FIG. 6, the display area DAA of the display panel 100 according to an embodiment includes the plurality of pixels PX arranged in a matrix form. The non-display area NDA of the display panel 100 according to an embodiment includes the scan driver 610, the emission driver 620, the data driver 700, a first distribution circuit 710, a second distribution circuit 720, the first pad portion PDA1, and a second pad portion PDA2.

The scan driver 610 may be disposed on the first side of the display area DAA, and the emission driver 620 may be disposed on the second side of the display area DAA. For example, the scan driver 610 may be disposed on one side of the display area DAA in the first direction DR1, and the emission driver 620 may be disposed on the other side of the display area DAA in the first direction DR1. However, embodiments of the present disclosure are not limited thereto, and the scan driver 610 and the emission driver 620 may be disposed on both the first side and the second side of the display area DAA.

The first pad portion PDA1 may include the plurality of first pads PD1 connected to pads or bumps of the circuit board 300 through a conductive adhesive member. The first pad portion PDA1 may be disposed on the third side of the display area DAA. For example, the first pad portion PDA1 may be disposed on one side of the display area DAA in the second direction DR2. The first pad portion PDA1 may be disposed outside the data driver 700 in the second direction DR2.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board formed of a rigid material or a flexible printed circuit board formed of a flexible material.

The second pad portion PDA2 may be disposed on the fourth side of the display area DAA. For example, the second pad portion PDA2 may be disposed on the other side of the display area DAA in the second direction DR2. The second pad portion PDA2 may be disposed outside the second distribution circuit 720 in the second direction DR2.

The first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be disposed on the third side of the display area DAA of the display panel 100. For example, the first distribution circuit 710 may be disposed on one side of the display area DAA in the second direction DR2.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. For example, the second distribution circuit 720 may be disposed on the other side of the display area DAA in the second direction DR2.

A cathode connection part CCA may be a region where a second electrode CAT (see FIG. 9) of a display element layer EML (see FIG. 9) is connected to the first driving voltage line VSL of the non-display area NDA. The cathode connection part CCA may be disposed outside at least one side of the display area DAA. For example, the cathode connection part CCA may be disposed outside at least on one side among the left side, the right side, the upper side, and the lower side of the display area DAA. Alternatively, the cathode connection part CCA may be disposed to surround the display area DAA as illustrated in FIG. 6 in order to minimize a deviation in the first driving voltage VSS caused by voltage drop (IR drop) or voltage rise (IR rising) of the second electrode CAT in the display area DAA.

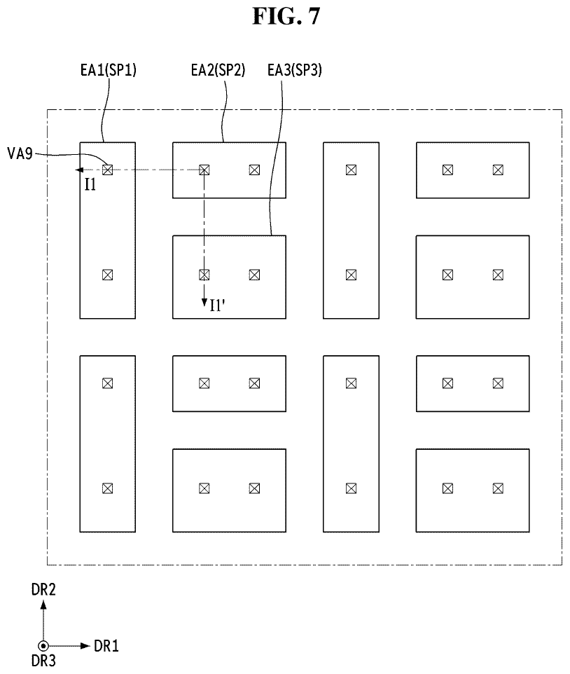

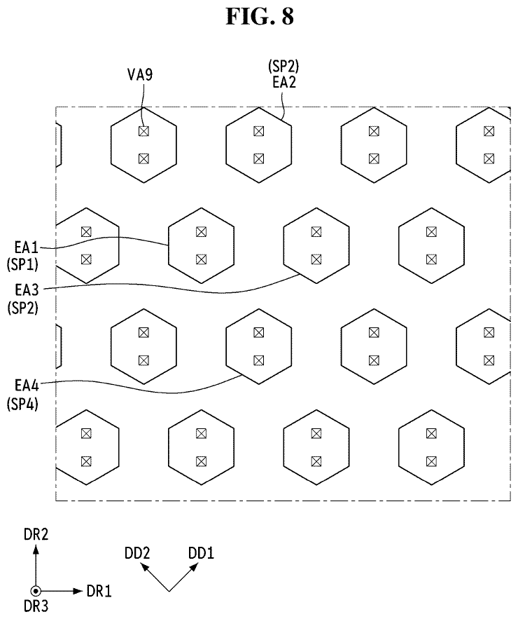

FIG. 7 is a schematic enlarged plan view illustrating an example of a display area illustrated in FIG. 6. FIG. 8 is a schematic enlarged plan view illustrating another example of the display area illustrated in FIG. 6.

Referring to FIGS. 7 and 8, each of the pixels PX includes the first emission area EA1 that is an emission area of the first sub-pixel SP1, the second emission area EA2 that is an emission area of the second sub-pixel SP2, and the third emission area EA3 that is an emission area of the third sub-pixel SP3.

The first emission area EA1, the second emission area EA2, and the third emission area EA3 may have, in plan view, a quadrilateral or hexagonal shape as illustrated in FIGS. 7 and 8, but embodiments of the present disclosure are not limited thereto. The first emission area EA1, the second emission area EA2, and the third emission area EA3 may have a polygonal shape other than a quadrangle or hexagon, a circular shape, an elliptical shape, or an atypical shape in plan view.

As illustrated in FIG. 7, in each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. In some aspects, the second emission area EA2 and the third emission area EA3 may be adjacent to each other in the second direction DR2. The area of the first emission area EA1, the area of the second emission area EA2, and the area of the third emission area EA3 may be different.

Alternatively, as illustrated in FIG. 8, the emission areas EA1, EA2, EA3, and EA4 may have a hexagonal shape in plan view. In this case, the first emission area EA1 and the third emission area EA3 may be adjacent in the first direction DR1, and the second emission area EA2 and the fourth emission area EA4 may be adjacent in the second direction DR2. In some aspects, the first emission area EA1 and the second emission area EA2 may be adjacent in a first diagonal direction DD1, and the second emission area EA2 and the third emission area EA3 may be adjacent in a second diagonal direction DD2. In some aspects, the first emission area EA1 and the fourth emission area EA4 may be adjacent in the second diagonal direction DD2, and the third emission area EA3 and the fourth emission area EA4 may be adjacent in the first diagonal direction DD1. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction perpendicular to the first diagonal direction DD1.

The first sub-pixel SP1 may emit first light, the second sub-pixel SP2 may emit second light, and the third sub-pixel SP3 may emit third light. Here, the first light may be light of a blue wavelength band, the second light may be light of a green wavelength band, and the third light may be light of a red wavelength band. For example, the blue wavelength band may be a wavelength band of light whose main peak wavelength is in the range of approximately 370 nm to 460 nm, the green wavelength band may be a wavelength band of light whose main peak wavelength is in the range of approximately 480 nm to 560 nm, and the red wavelength band may be a wavelength band of light whose main peak wavelength is in the range of approximately 600 nm to 750 nm.

As illustrated in FIG. 7, each of the plurality of pixels PX may include three emission areas EA1, EA2, and EA3, or may include four emission areas EA1, EA2, EA3, and EA4 as illustrated in FIG. 8. In this case, the fourth emission area EA4 may emit the same second light as the second emission area EA2, but embodiments of the present disclosure are not limited thereto.

The emission areas of the plurality of pixels PX may be arranged in a stripe structure in which the emission areas are arranged in the first direction DR1, a PenTile® structure in which the emission areas EA1, EA2, EA3, and EA4 are arranged in a rhombic shape as illustrated in FIG. 8, or a hexagonal structure in which the emission areas are arranged in a hexagonal shape.

FIG. 9 is a schematic cross-sectional view illustrating an example of the display panel taken along line I1-I1′ illustrated in FIG. 7.

Referring to FIG. 9, the display panel 100 includes a semiconductor backplane SBP, a light emitting element backplane EBP, the display element layer EML, an encapsulation layer TFE, an optical layer OPL, a cover layer CVL, and a polarizing plate POL.

The semiconductor backplane SBP includes the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 5.

The semiconductor substrate SSUB may be a silicon substrate, a germanium substrate, or a silicon-germanium substrate. The semiconductor substrate SSUB may be a substrate doped with a first type impurity. A plurality of well regions WA may be disposed on the top surface of the semiconductor substrate SSUB. The plurality of well regions WA may be regions doped with a second type impurity. The second type impurity may be different from the first type impurity. In an example in which the first type impurity is a p-type impurity, the second type impurity may be an n-type impurity. Alternatively, when the first type impurity is an n-type impurity, the second type impurity may be a p-type impurity.

Each of the plurality of well regions WA includes a source region SA corresponding to the source electrode of the pixel transistor PTR, a drain region DA corresponding to the drain electrode of the pixel transistor PTR, and a channel region CH disposed between the source region SA and the drain region DA.

A lower insulating film BINS may be disposed between a gate electrode GE and the well region WA. A side insulating film SINS may be disposed on the side surface of the gate electrode GE. The side insulating film SINS may be disposed on the lower insulating film BINS.

Each of the source region SA and the drain region DA may be a region doped with the first type impurity. The gate electrode GE of the pixel transistor PTR may overlap the well region WA in the third direction DR3, which is the thickness direction of the semiconductor substrate SSUB. The channel region CH may overlap the gate electrode GE in the third direction DR3. The source region SA may be disposed on one side of the gate electrode GE, and the drain region DA may be disposed on the other side of the gate electrode GE.

Each of the plurality of well regions WA further includes a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the first low-concentration impurity region LDD1 and the second low-concentration impurity region LDD2, thereby increasing the length of the channel region CH of each of the pixel transistors PTR.

A first semiconductor insulating film SINS1 may be disposed on the semiconductor substrate SSUB. A second semiconductor insulating film SINS2 may be disposed on the first semiconductor insulating film SINS1.

The plurality of contact terminals CTE may be disposed on the second semiconductor insulating film SINS2. Each of the plurality of contact terminals CTE may be connected to any one of the gate electrode GE, the source region SA, and the drain region DA of each of the pixel transistors PTR through a hole penetrating the first semiconductor insulating film SINS1 and the second semiconductor insulating film SINS2. The plurality of contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

A third semiconductor insulating film SINS3 may be disposed on a side surface of each of the plurality of contact terminals CTE. The top surface of each of the plurality of contact terminals CTE may be exposed without being covered by the third semiconductor insulating film SINS3.

Each of the first semiconductor insulating film SINS1, the second semiconductor insulating film SINS2, and the third semiconductor insulating film SINS3 may be formed of silicon carbonitride (SiCN) or a silicon oxide (SiOx)-based inorganic film, but embodiments of the present disclosure are not limited thereto.

The semiconductor substrate SSUB may be replaced with a glass substrate or a polymer resin substrate such as, for example, polyimide. In this case, thin film transistors may be disposed on the glass substrate or the polymer resin substrate. The glass substrate may be a rigid substrate that does not bend, and the polymer resin substrate may be a flexible substrate that can be bent or curved.

The light emitting element backplane EBP includes a plurality of conductive layers ML1 to ML8, a plurality of vias VA1 to VA9, and a plurality of interlayer insulating films INS1 to INS9.

The first to ninth interlayer insulating films INS1 to INS9 serve to insulate the first to eighth conductive layers ML1 to ML8. The first to eighth conductive layers ML1 to ML8 serve to connect the plurality of contact terminals CTE exposed from the semiconductor backplane SBP to thereby implement the circuit of the first sub-pixel SP1 illustrated in FIG. 5.

For example, the first to sixth transistors T1 to T6 are formed in the semiconductor backplane SBP, and the connection of the first to sixth transistors T1 to T6 and the first and second capacitors C1 and C2 is accomplished through the first to eighth conductive layers ML1 to ML8. In some aspects, the connection between the drain region corresponding to the drain electrode of the fourth transistor T4, the source region corresponding to the source electrode of the fifth transistor T5, and a first electrode AND of the light emitting element LE is also accomplished through the first to eighth conductive layers ML1 to ML8.

The first to eighth conductive layers ML1 to ML8 and the first to eighth vias VA1 to VA8 may be formed of substantially the same material. The first to eighth conductive layers ML1 to ML8 and the first to eighth vias VA1 to VA8 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The first to eighth vias VA1 to VA8 may be formed of substantially the same material. First to eighth interlayer insulating films INS1 to INS8 may be formed of a silicon oxide (SiOx)-based inorganic layer, but embodiments of the present disclosure are not limited thereto.

A ninth interlayer insulating film INS9 may be disposed on the eighth interlayer insulating film INS8 and the eighth conductive layer ML8. The ninth interlayer insulating film INS9 may be formed of a silicon oxide (SiOx)-based inorganic film, but embodiments of the present disclosure are not limited thereto.

Each of the ninth vias VA9 may penetrate the ninth interlayer insulating film INS9 and be connected to the exposed eighth conductive layer ML8. The ninth vias VA9 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

The display element layer EML may be disposed on the light emitting element backplane EBP. The display element layer EML may include the tenth and eleventh interlayer insulating films INS10 and INS11, reflective electrodes RL, the first electrodes AND, a light emitting stack IL, the second electrode CAT, a pixel defining film PDL, and a plurality of trenches TRC.

The reflective electrodes RL may be disposed on the ninth interlayer insulating film INS9. Each of the reflective electrodes RL may include at least one reflective electrode RL1, RL2, RL3, and RL4. For example, each of the reflective electrodes RL may include the first to fourth reflective electrodes RL1, RL2, RL3, and RL4 as illustrated in FIG. 9.

The first reflective electrodes RL1 may be disposed on the ninth interlayer insulating film INS9, and may be connected to the ninth via VA9. Each of the second reflective electrodes RL2 may be disposed on the first reflective electrode RL1 corresponding thereto. Each of the third reflective electrodes RL3 may be disposed on the second reflective electrode RL2 corresponding thereto. Each of the fourth reflective electrodes RL4 may be disposed on the third reflective electrode RL3 corresponding thereto.

Since the second reflective electrode RL2 is an electrode that substantially reflects light from the light emitting elements LE, the thickness of the second reflective electrode RL2 may be greater than the thickness of each of the first reflective electrode RL1, the third reflective electrode RL3, and the fourth reflective electrode RL4.

The first reflective electrodes RL1 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first reflective electrodes RL1 may contain titanium nitride (TiN), the second reflective electrodes RL2 may contain aluminum (Al), the third reflective electrodes RL3 may contain titanium nitride (TiN), and the fourth reflective electrodes RL4 may include titanium (Ti).

The tenth interlayer insulating film INS10 may be disposed on the ninth interlayer insulating film INS9. The tenth interlayer insulating film INS10 may be disposed between the reflective electrodes RL adjacent to each other. The tenth interlayer insulating film INS10 may be a film for flattening a stepped portion caused by the reflective electrodes RL. The eleventh interlayer insulating film INS11 may be disposed on the tenth interlayer insulating film INS10 and the reflective electrodes RL.

The tenth interlayer insulating film INS10 and the eleventh interlayer insulating film INS11 may be formed of a silicon oxide (SiOx)-based inorganic film, but embodiments of the present disclosure are not limited thereto.

The eleventh interlayer insulating film INS11 may be an optical auxiliary layer for adjusting the resonance distance of light emitted from the light emitting stack IL in at least one of the first sub-pixel SP1, the second sub-pixel SP2, or the third sub-pixel SP3. The thickness of the eleventh interlayer insulating film INS11 may be different in the first sub-pixel SP1, the second sub-pixel SP2, and the third sub-pixel SP3. That is, in order to adjust a distance from the reflective electrode RL to the second electrode CAT according to a main wavelength of light emitted from each of the first sub-pixel SP1, the second sub-pixel SP2, and the third sub-pixel SP3, the thickness of the eleventh interlayer insulating film INS11 may be set for each of the first sub-pixel SP1, the second sub-pixel SP2, and the third sub-pixel SP3.

For example, as illustrated in FIG. 9, the thickness of the eleventh interlayer insulating film INS11 in the first sub-pixel SP1 may be greater than the thickness of the eleventh interlayer insulating film INS11 in the second sub-pixel SP2, and the thickness of the eleventh interlayer insulating film INS11 in the second sub-pixel SP2 may be greater than the thickness of the eleventh interlayer insulating film INS11 in the third sub-pixel SP3. In this case, the distance between the first electrode AND and the reflective electrode RL in the first sub-pixel SP1 is greater than the distance between the first electrode AND and the reflective electrode RL in the second sub-pixel SP2. In some aspects, the distance between the first electrode AND and the reflective electrode RL in the second sub-pixel SP2 is greater than the distance between the first electrode AND and the reflective electrode RL in the third sub-pixel SP3.

Each of the tenth vias VA10 may penetrate the eleventh interlayer insulating film INS11 and be connected to the exposed fourth reflective electrode RL4. The tenth vias VA10 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the tenth via VA10 in the first sub-pixel SP1 may be greater than the thickness of the tenth via VA10 in the second sub-pixel SP2, and the thickness of the tenth via VA10 in the second sub-pixel SP2 may be greater than the thickness of the tenth via VA10 in the third sub-pixel SP3.

The first electrode AND of each of the light emitting elements LE may be disposed on the eleventh interlayer insulating film INS11 and connected to the tenth via VA10. The first electrode AND of each of the light emitting elements LE may be connected to the drain region DA or source region SA of the pixel transistor PTR through the tenth via VA10, the reflective electrode RL, the first to ninth vias VA1 to VA9, the first to eighth metal layers ML1 to ML8, and the contact terminal CTE. The first electrode AND of each of the light emitting elements LE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first electrode AND of each of the light emitting elements LE may be titanium nitride (TiN).

The pixel defining film PDL may be disposed on a part of the first electrode AND of each of the light emitting elements LE. The pixel defining film PDL may cover the edge of the first electrode AND of each of the light emitting elements LE. The pixel defining film PDL may partition the first emission areas EA1, the second emission areas EA2, and the third emission areas EA3. Each of the first emission area EA1, the second emission area EA2, and the third emission area EA3 may be an area where the light emitting element LE including the first electrode AND, the light emitting stack IL, and the second electrode CAT is disposed.

The first emission area EA1 may be defined as an area in which the first electrode AND, the light emitting stack IL, and the second electrode CAT are sequentially stacked in the first sub-pixel SP1 to emit light. The second emission area EA2 may be defined as an area in which the first electrode AND, the light emitting stack IL, and the second electrode CAT are sequentially stacked in the second sub-pixel SP2 to emit light. The third emission area EA3 may be defined as an area in which the first electrode AND, the light emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be disposed on the edge of the first electrode AND of each of the light emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed of a silicon oxide (SiOx)-based inorganic film. Alternatively, the first pixel defining film PDL1 and the third pixel defining film PDL3 may be formed of a silicon nitride (SiNx)-based inorganic film, whereas the second pixel defining film PDL2 may be formed of a silicon oxide (SiOx)-based inorganic film. The first pixel defining film PDL1, the second pixel defining film PDL2, and the third pixel defining film PDL3 may each have a thickness of about 500 Å.

In order to reduce or prevent the likelihood of the first encapsulation inorganic film TFE1 being cut off due to the step coverage, the first pixel defining film PDL1, the second pixel defining film PDL2, and the third pixel defining film PDL3 may have a cross-sectional structure having a stepped portion. Step coverage refers to the ratio of the degree of thin film coated on an inclined portion to the degree of thin film coated on a flat portion. The lower the step coverage, the more likely it is that the thin film will be cut off at inclined portions.

Each of the plurality of trenches TRC may penetrate the first pixel defining film PDL1, the second pixel defining film PDL2, and the third pixel defining film PDL3. The eleventh interlayer insulating film INS11 may be partially recessed at each of the plurality of trenches TRC.

At least one trench TRC may be disposed between the neighboring sub-pixels SP1, SP2, and SP3. Although FIG. 9 illustrates that two trenches TRC are disposed between the neighboring sub-pixels SP1, SP2, and SP3, embodiments of the present disclosure are not limited thereto.

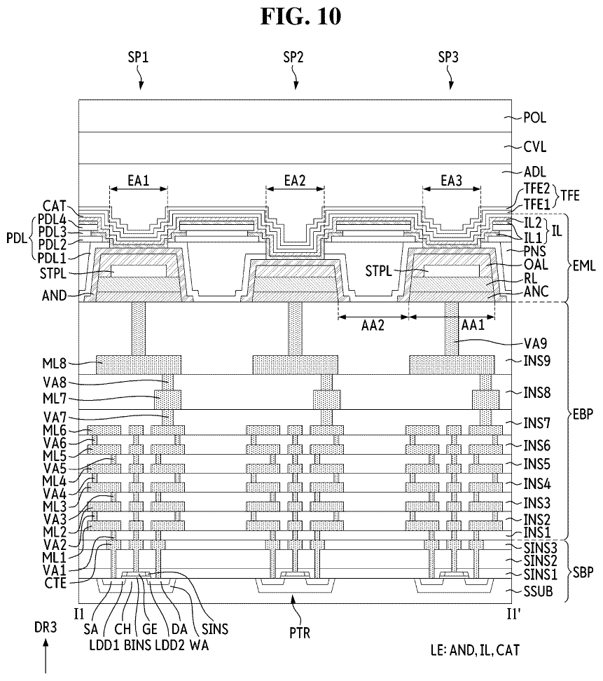

The light emitting stack IL may include a plurality of stack layers IL1, IL2, and IL3. FIG. 9 illustrates that the light emitting stack IL has a three-tandem structure including a first stack layer IL1, a second stack layer IL2, and a third stack layer IL3, but embodiments of the present disclosure are not limited thereto. For example, the light emitting stack IL may have a two-tandem structure including two stack layers as illustrated in FIG. 10.

In the three-tandem structure, the light emitting stack IL may have a tandem structure including a plurality of intermediate layers IL1, IL2, and IL3 that emit different lights. For example, the light emitting stack IL may include the first stack layer IL1 that emits first light, the second stack layer IL2 that emits second light, and the third stack layer IL3 that emits third light. The first stack layer IL1, the second stack layer IL2, and the third stack layer IL3 may be sequentially stacked.

The first stack layer IL1 may have a structure in which a first hole transport layer, a first light emitting layer that emits the first light, and a first electron transport layer are sequentially stacked. The second stack layer IL2 may have a structure in which a second hole transport layer, a second light emitting layer that emits the second light, and a second electron transport layer are sequentially stacked. The third stack layer IL3 may have a structure in which a third hole transport layer, a third light emitting layer that emits the third light, and a third electron transport layer are sequentially stacked.

A first charge generation layer for supplying charges to the second stack layer IL2 and supplying electrons to the first stack layer IL1 may be disposed between the first stack layer IL1 and the second stack layer IL2. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

A second charge generation layer for supplying charges to the third stack layer IL3 and supplying electrons to the second stack layer IL2 may be disposed between the second stack layer IL2 and the third stack layer IL3. The second charge generation layer may include an N-type charge generation layer that supplies electrons to the second stack layer IL2 and a P-type charge generation layer that supplies holes to the third stack layer IL3.

The first stack layer IL1 may be disposed on the first electrodes AND and the pixel defining film PDL, and a residual film RIL disposed on the bottom surface of each trench TRC may be the same material as the first stack layer IL1. Due to the trench TRC, the first stack layer IL1 may be cut off between the neighboring sub-pixels SP1, SP2, and SP3. The second stack layer IL2 may be disposed on the first stack layer IL1. Due to the trench TRC, the second stack layer IL2 may be cut off between the neighboring sub-pixels SP1, SP2, and SP3. A cavity ESS or an empty space may be disposed between the residual film IL and the second stack layer IL2 in the trench TRC. The third stack layer IL3 may be disposed on the second stack layer IL2. The third stack layer IL3 is not cut off by the trench TRC and may be disposed such that the third stack layer IL3 covers the second stack layer IL2 in each of the trenches TRC.

In the three-tandem structure, each of the plurality of trenches TRC may be a structure for cutting off the first to third hole transport layers, the first charge generation layer, and the second charge generation layer of the first to third stack layers IL1, IL2, and IL3 of the display element layer EML between the neighboring sub-pixels SP1, SP2, and SP3. In some aspects, in the two-tandem structure, each of the plurality of trenches TRC may be a structure for cutting off the charge generation layer and the lower stack layer disposed between the lower stack layer and the upper stack layer.

In order to stably cut off the first and second stack layers IL1 and IL2 of the display element layer EML between the neighboring sub-pixels SP1, SP2, and SP3, the height of each of the plurality of trenches TRC may be greater than the height of the pixel defining film PDL. The height of each of the plurality of trenches TRC refers to the length of each of the plurality of trenches TRC in the third direction DR3. The height of the pixel defining film PDL refers to the length of the pixel defining film PDL in the third direction DR3. In order to cut off the charge generation layers and the hole transport layers of the light emitting stack IL of the display element layer EML between the neighboring sub-pixels SP1, SP2, and SP3, a different structure may be present instead of the trench TRC. For example, instead of the trench TRC, a reverse tapered partition wall may be disposed on the pixel defining film PDL.

In some aspects, FIG. 9 illustrates that the light emitting stack IL that emits light is disposed in the first emission area EA1, the second emission area EA2, and the third emission area EA3, but embodiments of the present disclosure are not limited thereto. For example, instead of the light emitting stack IL, the first light emitting layer may be disposed in the first emission area EA1, and may be omitted from the second emission area EA2 and the third emission area EA3. Furthermore, the second light emitting layer may be disposed in the second emission area EA2 and may be omitted from the first emission area EA1 and the third emission area EA3. Furthermore, the third light emitting layer may be disposed in the third emission area EA3 and may be omitted from the first emission area EA1 and the second emission area EA2. In this case, first to third color filters CF1, CF2, and CF3 of the optical layer OPL may be omitted.

The second electrode CAT may be disposed on the light emitting stack IL. That is, the second electrode CAT may be disposed on the third stack layer IL3. The second electrode CAT may be formed of a transparent conductive material (TCO) such as, for example, ITO or IZO that can transmit light or a semi-transmissive conductive material such as, for example, magnesium (Mg), silver (Ag), or an alloy of Mg and Ag. In an example in which the second electrode CAT is formed of a semi-transmissive conductive material, the light emission efficiency may be improved in each of the first to third sub-pixels SP1, SP2, and SP3 due to a micro-cavity effect.

The encapsulation layer TFE may be disposed on the display element layer EML. The encapsulation layer TFE may include at least one inorganic film TFE1 and TFE3 to prevent oxygen or moisture from permeating into the display element layer EML. The first encapsulation inorganic film TFE1 may be disposed on the second electrode CAT, and the second encapsulation inorganic film TFE3 may be disposed above the first encapsulation inorganic film TFE1. The first encapsulation inorganic film TFE1 and the second encapsulation inorganic film TFE3 may be formed of multiple layers in which one or more inorganic films of silicon nitride (SiNx), silicon oxynitride (SiON), silicon oxide (SiOx), titanium oxide (TiOx), and aluminum oxide (AlOx) layers are alternately stacked.

In some aspects, the encapsulation layer TFE may include at least one organic film TFE2 to protect the display element layer EML from foreign substances such as, for example, dust. The encapsulating organic film TFE2 may be disposed between the first encapsulating inorganic film TFE1 and the second encapsulating inorganic film TFE3. The encapsulation organic film TFE2 may be a monomer. Alternatively, the encapsulation organic film TFE2 may be an organic film such as, for example, acryl resin, epoxy resin, phenolic resin, polyamide resin, polyimide resin or the like.

An adhesive layer ADL may be a layer for bonding the encapsulation layer TFE to the optical layer OPL. The adhesive layer ADL may be a double-sided adhesive member. In some aspects, the adhesive layer ADL may be a transparent adhesive member such as, for example, a transparent adhesive or a transparent adhesive resin.

The optical layer OPL includes a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be disposed on the adhesive layer ADL.

The first color filter CF1 may overlap the first emission area EA1 of the first sub-pixel SP1. The first color filter CF1 may transmit light of the first color, i.e., light of a blue wavelength band. The blue wavelength band may be about 370 nm to about 460 nm. Thus, the first color filter CF1 may transmit light of the first color among light emitted from the first emission area EA1.

The second color filter CF2 may overlap the second emission area EA2 of the second sub-pixel SP2. The second color filter CF2 may transmit light of the second color, i.e., light of a green wavelength band. The green wavelength band may be about 480 nm to about 560 nm. Thus, the second color filter CF2 may transmit light of the second color among light emitted from the second emission area EA2.

The third color filter CF3 may overlap the third emission area EA3 of the third sub-pixel SP3. The third color filter CF3 may transmit light of the third color, i.e., light of a red wavelength band. The red wavelength band may be about 600 nm to about 750 nm. Thus, the third color filter CF3 may transmit light of the third color among light emitted from the third emission area EA3.

The plurality of lenses LNS may be disposed on the first color filter CF1, the second color filter CF2, and the third color filter CF3, respectively. Each of the plurality of lenses LNS may be a structure for increasing the proportion of light directed to the front of the display device 10. Each of the plurality of lenses LNS may have a cross-sectional shape that is convex in an upward direction.

The filling layer FIL may be disposed on the plurality of lenses LNS. The filling layer FIL may have a predetermined refractive index such that light travels in the third direction DR3 at an interface between the filling layer FIL and the plurality of lenses LNS. Further, the filling layer FIL may be a planarization layer. The filling layer FIL may be an organic film such as, for example, acrylic resin, epoxy resin, phenolic resin, polyamide resin, or polyimide resin.

The cover layer CVL may be disposed on the filling layer FIL. The cover layer CVL may be a glass substrate or a polymer resin. In an example in which the cover layer CVL is a glass substrate, the cover layer CVL may be attached onto the filling layer FIL. In this case, the filling layer FIL may serve to bond the cover layer CVL. In an example in which the cover layer CVL is a glass substrate, the cover layer CVL may serve as an encapsulation substrate. In an example in which the cover layer CVL is a polymer resin, the cover layer CVL may be directly applied onto the filling layer FIL.

The polarizing plate may be disposed on one surface of the cover layer CVL. The polarizing plate may be a structure for reducing or preventing visibility degradation caused by reflection of external light. The polarizing plate may include a linear polarizing plate and a phase retardation film. For example, the phase retardation film may be a λ/4 plate (quarter-wave plate), but embodiments of the present disclosure are not limited thereto. However, when visibility degradation caused by reflection of external light is sufficiently overcome by the first to third color filters CF1, CF2, and CF3, the polarizing plate may be omitted.

FIG. 10 is a schematic cross-sectional view illustrating another example of the display panel taken along line I1-I1′ illustrated in FIG. 7.

The embodiment of FIG. 10 differs from the embodiment of FIG. 9 in that the first electrode AND of each of the light emitting elements LE is in contact with and electrically connected to the side surface of a connection electrode ANC connected to the eighth conductive layer ML8. The embodiment of FIG. 10 also differs from the embodiment of FIG. 9 in that the trench TRC is omitted, and instead, the third pixel defining film PDL3 and a fourth pixel defining film PDL4 have an cave-shaped or mushroom-shaped cross-sectional structure. In the embodiment of FIG. 10, redundant description of parts already described in the embodiment of FIG. 9 will be omitted.

Referring to FIG. 10, the plurality of connection electrodes ANC may be respectively disposed on first portions AA1 of the ninth interlayer insulating film INS9. Each of the plurality of connection electrodes ANC may be disposed on the first portion AA1 of the ninth interlayer insulating film INS9 corresponding thereto. A plurality of connection electrodes ANC may be formed of any one of copper (Cu), aluminum (Al), tungsten (W), molybdenum (Mo), chromium (Cr), gold (Au), titanium (Ti), nickel (Ni), and neodymium (Nd), an alloy including any one of them, or a transparent conductive oxide. For example, the plurality of connection electrodes ANC may include titanium (Ti), titanium nitride (TiN), indium tin oxide (ITO), or indium zinc oxide (IZO), but the present disclosure is limited thereto.

A plurality of reflective electrodes RL may be respectively disposed on the plurality of connection electrodes ANC. Each of the plurality of reflective electrodes RL may be disposed on the connection electrode ANC corresponding thereto. The plurality of reflective electrodes RL may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, each of the plurality of reflective electrodes RL may include aluminum (Al) having high reflectivity.

A plurality of optical auxiliary films OAL may be respectively disposed on the plurality of reflective electrodes RL. Each of the plurality of optical auxiliary films OAL may be disposed on the reflective electrode RL corresponding thereto. The plurality of optical auxiliary films OAL may be formed of a silicon oxide (SiOx)-based inorganic film, but embodiments of the present disclosure are not limited thereto.

In each of the first emission area EA1 and the third emission area EA3, a step layer STPL may be disposed on the reflective electrode RL, and the optical auxiliary film OAL may be disposed on the step layer STPL. In the second emission area EA2, for example, only the optical auxiliary film OAL may be disposed on the reflective electrode RL. The thicknesses of the optical auxiliary film OAL may be substantially the same in the first emission area EA1, the second emission area EA2, and the third emission area EA3.

Due to the step layer STPL, the distance between the reflective electrode RL and the first electrode AND in the first emission area EA1 and the third emission area EA3 may be greater than the distance between the reflective electrode RL and the first electrode AND in the second emission area EA2. The thickness of the step layer STPL and the thickness of the optical auxiliary layer OAL may be set in consideration of the wavelength and resonance distance of light emitted from the first stack layer IL1 of the light emitting stack IL, and further, the wavelength and resonance distance of light emitted from the second stack layer IL2 of the light emitting stack IL.

Each of the light emitting elements LE may include the first electrode AND, a light emitting stack IL, and a second electrode CAT.

The first electrode AND of each of the light emitting elements LE may be disposed on the optical auxiliary film OAL corresponding thereto. Since the connection electrode ANC, the reflective electrode RL, and the optical auxiliary layer OAL are sequentially stacked, the first electrode AND of each of the light emitting elements LE may be disposed on the top surface and the side surface of the optical auxiliary layer OAL, the side surface of the reflective electrode RL, and the side surface of the connection electrode ANC. Accordingly, the first electrode AND of each of the light emitting elements LE may be in contact with and electrically connected to the side surface of the reflective electrode RL and the side surface of the connection electrode ANC. Therefore, compared to when the first electrode AND of each of the light emitting elements LE is connected to the reflective electrode RL exposed through a through hole penetrating the optical auxiliary film OAL, the number of mask processes may be reduced, thereby lowering manufacturing cost and increasing manufacturing efficiency.

The first electrode AND of each of the light emitting elements LE may be connected to the drain region DA or the source region SA of the pixel transistor PTR through the connection electrode ANC, the first to ninth vias VA1 to VA9, the first to eighth conductive layers ML1 to ML8, and the contact terminal CTE.

The ninth interlayer insulating film INS9 may include the first portion AA1 that overlaps the connection electrode ANC in the third direction DR3 and a second portion AA2 that does not overlap the connection electrode ANC in the third direction DR3. The thickness of the first portion AA1 and the thickness of the second portion AA2 of the ninth interlayer insulating film INS9 may be substantially the same.

Alternatively, the thickness of the first portion AA1 of the ninth interlayer insulating film INS9 may be greater than the thickness of the second portion AA2 of the ninth interlayer insulating film INS9. In this case, the side surface of the first portion AA1 of the ninth interlayer insulating film INS9 may be exposed, and the first electrode AND of each of the light emitting elements LE may be disposed on the exposed side surface of the first portion AA1 of the ninth interlayer insulating film INS9.

The first electrode AND of each of the light emitting elements LE may be formed of any one of copper (Cu), aluminum (Al), tungsten (W), molybdenum (Mo), chromium (Cr), gold (Au), titanium (Ti), nickel (Ni), and neodymium (Nd), an alloy including any one of them, or a transparent conductive oxide. For example, the first electrode AND of each of the light emitting elements LE may include titanium (Ti), titanium nitride (TiN), indium tin oxide (ITO), or indium zinc oxide (IZO), but the present disclosure is limited thereto.

The pixel defining film PDL may be disposed on a part of the first electrode AND of each of the light emitting elements LE. The pixel defining film PDL may cover the edge of the first electrode AND of each of the light emitting elements LE. The pixel defining film PDL may partition the first emission areas EA1, the second emission areas EA2, and the third emission areas EA3.

The pixel defining film PDL may include first to fourth pixel defining films PDL1, PDL2, PDL3, and PDL4.

The first pixel defining film PDL1 may be disposed on the first electrode AND of each of the light emitting elements LE. Specifically, the first pixel defining film PDL1 may cover a part of the top surface of the first electrode AND disposed on the optical auxiliary film OAL. Further, the first pixel defining film PDL1 may cover the first electrode AND disposed on the side surface of the connection electrode ANC, the side surface of the reflective electrode RL, and the side surface of the optical auxiliary film OAL. The first pixel defining film PDL1 may be disposed on the top surface of the second portion AA2 of the ninth interlayer insulating film INS9.

A planarization film PNS is a film for flattening the stepped portion caused by the connection electrode ANC, the reflective electrode RL, and the optical auxiliary film OAL.

The planarization film PNS may be disposed on the first pixel defining film PDL1 covering the first electrode AND disposed on the side surface of the connection electrode ANC, the side surface of the reflective electrode RL, and the side surface of the optical auxiliary film OAL. The planarization film PNS may be disposed on the first pixel defining film PDL1 disposed on the second portion AA2 of the ninth interlayer insulating film INS9.

The planarization film PNS may be disposed between the connection electrodes ANC adjacent in the first direction DR1 or the second direction DR2. The planarization film PNS may be disposed between the reflective electrodes RL adjacent in the first direction DR1 or the second direction DR2. The planarization film PNS may be disposed between the optical auxiliary films OAL adjacent in the first direction DR1 or the second direction DR2.

The step layer STPL is not present in the second emission area EA2, whereas the step layer STPL is present in each of the first emission area EA1 and the third emission area EA3. Accordingly, the heights of the connection electrode ANC, the reflective electrode RL, and the optical auxiliary film OAL in the second emission area EA2 may be less than the heights of the connection electrode ANC, the reflective electrode RL, the step layer STPL, and the optical auxiliary film OAL in the first emission area EA1 and the third emission area EA3. Therefore, the planarization film PNS may cover the top surface of the first pixel defining film PDL1 disposed on the top surface of the first electrode AND disposed in the second emission area EA2.

In contrast, the top surface of the planarization film PNS may be flatly connected to the top surface of the first pixel defining film PDL1 disposed on the top surface of the first electrode AND disposed in the first emission area EA1 and the third emission area EA3. That is, the planarization film PNS may not cover the top surface of the first pixel defining film PDL1 disposed on the top surface of the first electrode AND disposed in each of the first emission area EA1 and the third emission area EA3.

The second pixel defining film PDL2 may be disposed on the first pixel defining film PDL1 and the planarization film PNS, the third pixel defining film PDL3 may be disposed on the second pixel defining film PDL2, and the fourth pixel defining film PDL4 may be disposed on the third pixel defining film PDL3. The first pixel defining film PDL1 and the third pixel defining film PDL3 may be formed of a silicon nitride (SiNx)-based inorganic film, whereas the second pixel defining film PDL2, the fourth pixel defining film PDL4, and the planarization film PNS may be formed of a silicon oxide (SiOx)-based inorganic film. The first pixel defining film PDL1 is formed of a material different from a material of the planarization film PNS, and thus may serve as a stopper in a chemical mechanical polishing process for the planarization film PNS.

When the planarization film PNS and the second pixel defining film PDL2 are both formed as a silicon oxide (SiOx)-based inorganic film, the planarization film PNS and the second pixel defining film PDL2 may be formed as a single film.

Since the length of the third pixel defining film PDL3 in one direction is less than the length of the fourth pixel defining film PDL4 in one direction, the bottom surface of the fourth pixel defining film PDL4 may be exposed without being covered by the third pixel defining film PDL3. That is, the third pixel defining film PDL3 and the fourth pixel defining film PDL4 may have an caves-shaped or mushroom-shaped cross-sectional structure.

The light emitting stack IL may be disposed on the first electrode AND and the pixel defining film PDL. The light emitting stack IL may include the first stack layer IL1 and the second stack layer IL2 that emit different lights. In an example in which the light emitting stack IL has a two-tandem structure, one of the first stack layer IL1 and the second stack layer IL2 may emit light that includes the wavelength range of any one of the first light, the second light, and the third light, and the other may emit light that includes the wavelength ranges of the other two lights. For example, the first stack layer IL1 may emit light that includes the wavelength range of the first light and the wavelength range of the third light, and the second stack layer IL2 may emit light that includes the wavelength range of the second light. Here, the first light may be light of a blue wavelength band, the second light may be light of a green wavelength band, and the third light may be light of a red wavelength band.

A charge generation layer for supplying charges to the second stack layer IL2 and supplying electrons to the first stack layer IL1 may be disposed between the first stack layer IL1 and the second stack layer IL2. The charge generation layer may include an n-type charge generation layer that supplies electrons to the first stack layer IL1 and a p-type charge generation layer that supplies holes to the second stack layer IL2. The N-type charge generation layer may include a dopant of a metal material.

The first stack layer IL1 is not formed on the bottom surface of the fourth pixel defining film PDL4 that is exposed without being covered by the third pixel defining film PDL3, and thus may be cut off by the caves-shaped or mushroom-shaped cross-sectional structure of the third pixel defining film PDL3 and the fourth pixel defining film PDL4. In this case, the first hole transport layer of the first stack layer IL1, and a charge generation layer disposed between the first stack layer IL1 and the second stack layer IL2 may also be cut off. Further, although FIG. 10 illustrates that the second stack layer IL2 is connected without being cut off, the second hole transport layer of the second stack layer IL2 may be cut off, and the second electron transport layer of the second stack layer IL2 may be connected without being cut off. Therefore, it is possible to prevent a leakage current from flowing through the first hole transport layer of the first stack layer IL1, the second hole transport layer of the second stack layer IL2, and the charge generation layer between the adjacent emission areas EA1, EA2, and EA3. Accordingly, it is possible to prevent the light emitting stack IL in the adjacent emission areas EA1, EA2, and EA3 from emitting light other than the originally intended light due to the influence of the described current.

Although FIG. 10 illustrates a two-tandem structure in which the light emitting stack IL includes two stack layers IL1 and IL2, embodiments of the present disclosure are not limited thereto. For example, the light emitting stack IL may have a three-tandem structure including three stack layers as illustrated in FIG. 9. In this case, the light emitting stack IL may be designed such that the charge generation layer between the first stack layer IL1 and the second stack layer IL2, and the charge generation layer between the second stack layer IL2 and the third stack layer IL3 are cut off by adjusting the height of the third pixel defining film PDL3. Alternatively, as illustrated in FIG. 9, the trench TRC penetrating the first pixel defining film PDL1, the planarization film PNS, the second pixel defining film PDL2, and the third pixel defining film PDL3 may be added. In this case, the trench TRC may penetrate at least a part of the ninth interlayer insulating film INS9, but embodiments of the present disclosure are not limited thereto.

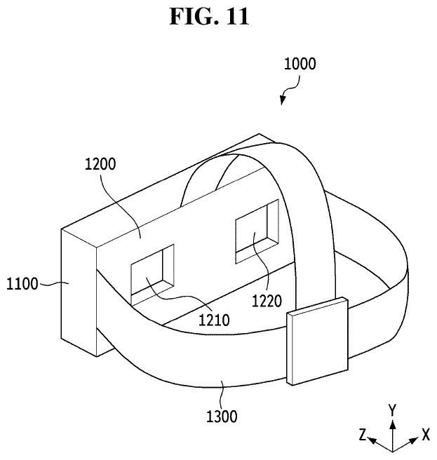

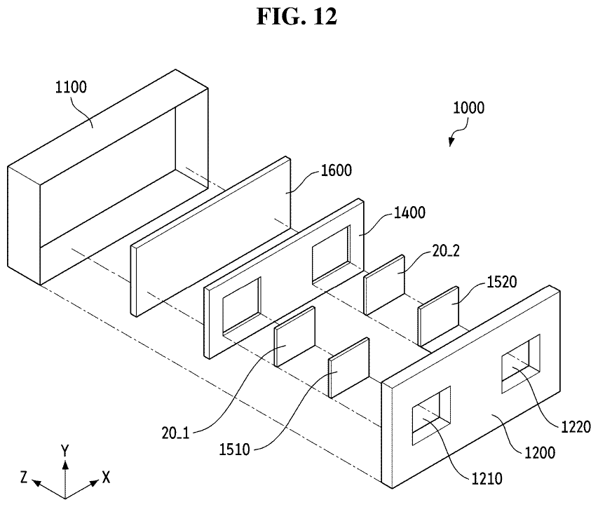

FIG. 11 is a schematic perspective view illustrating one example of a head mounted display. FIG. 12 is a schematic exploded perspective view illustrating the head mounted display illustrated in FIG. 11.

Referring to FIGS. 11 and 12, a head mounted display 1000 according to an embodiment includes a first display device 20_1, a second display device 20_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 20_1 provides an image to the user's left eye, and the second display device 20_2 provides an image to the user's right eye. Since each of the first display device 20_1 and the second display device 20_2 is substantially the same as the display device 20 described in conjunction with FIGS. 3 to 10, the description of the first display device 20_1 and the second display device 20_2 will be omitted.

The first optical member 1510 may be disposed between the first display device 20_1 and the first eyepiece 1210. The second optical member 1520 may be disposed between the second display device 20_2 and the second eyepiece 1220. Each of the first optical member 1510 and the second optical member 1520 may include at least one convex lens.

The middle frame 1400 may be disposed between the first display device 20_1 and the control circuit board 1600 and between the second display device 20_2 and the control circuit board 1600. The middle frame 1400 serves to support and fix the first display device 20_1, the second display device 20_2, and the control circuit board 1600.

The control circuit board 1600 may be disposed between the middle frame 1400 and the display device housing 1100. The control circuit board 1600 may be connected to the first display device 20_1 and the second display device 20_2 through the connector. The control circuit board 1600 may convert an image source inputted from the outside into the digital video data DATA, and transmit the digital video data DATA to the first display device 20_1 and the second display device 20_2 through the connector.

The control circuit board 1600 may transmit the digital video data DATA corresponding to a left-eye image optimized for the user's left eye to the first display device 20_1, and may transmit the digital video data DATA corresponding to a right-eye image optimized for the user's right eye to the second display device 20_2. Alternatively, the control circuit board 1600 may transmit the same digital video data DATA to the first display device 20_1 and the second display device 20_2.

The display device housing 1100 serves to accommodate the first display device 20_1, the second display device 20_2, the middle frame 1400, the first optical member 1510, the second optical member 1520, and the control circuit board 1600. The housing cover 1200 is disposed such that the housing cover 1200 covers an open surface of the display device housing 1100. The housing cover 1200 may include the first eyepiece 1210 at which the user's left eye is located and the second eyepiece 1220 at which the user's right eye is located. FIGS. 11 and 12 illustrate that the first eyepiece 1210 and the second eyepiece 1220 are disposed separately, but embodiments of the present disclosure are not limited thereto. The first eyepiece 1210 and the second eyepiece 1220 may be combined into one.

The first eyepiece 1210 may be aligned with the first display device 20_1 and the first optical member 1510, and the second eyepiece 1220 may be aligned with the second display device 20_2 and the second optical member 1520. Therefore, the user may view, through the first eyepiece 1210, the image of the first display device 20_1 magnified as a virtual image by the first optical member 1510, and may view, through the second eyepiece 1220, the image of the second display device 20_2 magnified as a virtual image by the second optical member 1520.

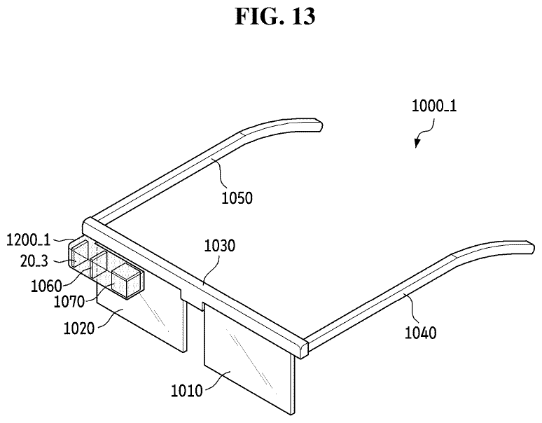

The head mounted band 1300 serves to secure the display device housing 1100 to the user's head such that the first eyepiece 1210 and the second eyepiece 1220 of the housing cover 1200 remain located on the user's left and right eyes, respectively. In an example in which the housing cover 1200 is implemented to be lightweight and compact, the head mounted display 1000 may be provided with, as illustrated in FIG. 13, an eyeglass frame instead of the head mounted band 1300.

FIG. 13 is a schematic perspective view illustrating another example of a head mounted display.

Referring to FIG. 13, a head mounted display 1000_1 according to an embodiment may be an eyeglasses-type display device in which a display device housing 1200_1 is implemented in a lightweight and compact manner. The head mounted display 1000_1 according to an embodiment may include a display device 20_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 20_3, the optical member 1060, and the optical path changing member 1070. The image displayed on the display device 20_3 may be magnified by the optical member 1060, and the image may be provided to the user's right eye through the right eye lens 1020 after the optical path of the image is changed by the optical path changing member 1070. As a result, the user may view an augmented reality image, through the right eye, in which a virtual image displayed on the display device 20_3 and a real image seen through the right eye lens 1020 are combined.

FIG. 13 illustrates that the display device housing 1200_1 is disposed at the right end of the support frame 1030, but embodiments of the present disclosure are not limited thereto. For example, the display device housing 1200_1 may be disposed at the left end of the support frame 1030, and in this case, the image of the display device 20_3 may be provided to the user's left eye. Alternatively, the display device housing 1200_1 may be disposed at both the left and right ends of the support frame 1030, and in this case, the user may view the image displayed on the display device 20_3 through both the left and right eyes.

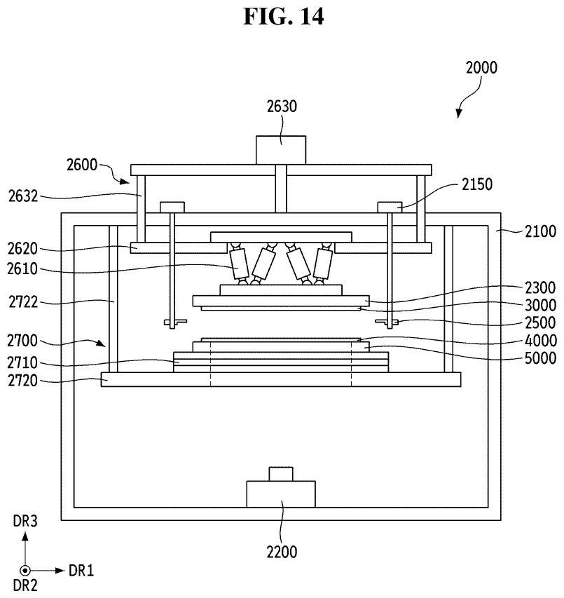

FIG. 14 is a schematic diagram illustrating a mask stage and a deposition apparatus including the same according to an embodiment of the present disclosure.

Referring to FIG. 14, a deposition apparatus 2000 according to an embodiment of the present disclosure may be used to form deposition material layers on a backplane substrate 3000. For example, the deposition apparatus 2000 according to an embodiment of the present disclosure may be used for forming light emitting material layers on the backplane substrate 3000 for manufacturing a display panel. In this case, as illustrated in FIGS. 9 and 10, the semiconductor backplane SBP and the light emitting element backplane EBP may be arranged on the backplane substrate 3000, and the electrode patterns AND such as, for example, anode electrodes and the pixel defining film PDL having openings exposing the electrode patterns AND may be disposed on the light emitting element backplane EBP.

The deposition apparatus 2000 according to an embodiment of the present disclosure may be used for forming light emitting material layers respectively on the electrode patterns AND. For example, the deposition apparatus 2000 according to an embodiment of the present disclosure may be used for forming first light emitting material layers for emitting first light having a blue wavelength band on the electrode patterns AND respectively arranged in the first emission areas EA1, second light emitting material layers for emitting second light having a green wavelength band on the electrode patterns AND respectively arranged in the second emission areas EA2, and third light emitting material layers for emitting third light having a blue wavelength band on the electrode patterns AND respectively arranged in the third emission areas EA3.

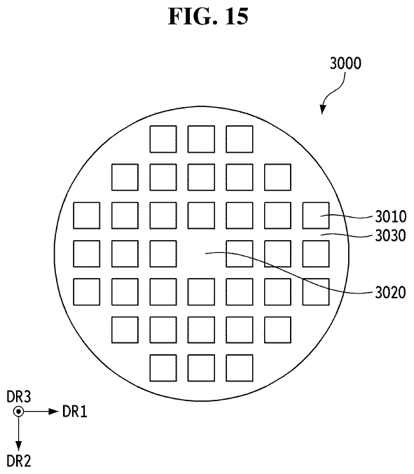

FIG. 15 is a schematic bottom view illustrating an example of the backplane substrate illustrated in FIG. 14.

Referring to FIG. 15, the backplane substrate 3000 may include a plurality of display cell regions 3010 and a non-display cell region 3020. Further, the backplane substrate 3000 may include a scribe lane region 3030 disposed between the display cell regions 3010 and the non-display cell region 3020. The display cell regions 3010 and the non-display cell region 3020 may be arranged in a matrix form along the first direction DR1 and the second direction DR2 intersecting the first direction DR1, and the display cell regions 3010 may be respectively individualized into a plurality of display panels 100 by a dicing process after a display manufacturing process is completed. For example, the first direction DR1 may be a first horizontal direction, and the second direction DR2 may be a second horizontal direction perpendicular to the first direction DR1. In this case, the first direction DR1 may be an X-axis direction, and the second direction DR2 may be a Y-axis direction.

Although not illustrated in detail, each of the display cell regions 3010 may include the semiconductor backplane SBP and the light emitting element backplane EBP disposed on the semiconductor backplane SBP, and the plurality of electrode patterns AND may be disposed on the light emitting element backplane EBP. Further, the pixel defining film PDL may be disposed on the light emitting element backplane EBP, and the pixel defining film PDL may have openings exposing the electrode patterns AND. However, the semiconductor backplane SBP, the light emitting element backplane EBP, and the electrode patterns AND may not be arranged on the non-display cell region 3020. For example, the non-display cell region 3020 may be disposed on the central portion of the backplane substrate 3000, and may include a plurality of insulating films INS1 to INS11 and the pixel defining film PDL, as illustrated in FIG. 9. In another example, the non-display cell region may include the plurality of insulating films INS1 to INS9, a planarizing film PNS, and the pixel defining film PDL, as illustrated in FIG. 10.

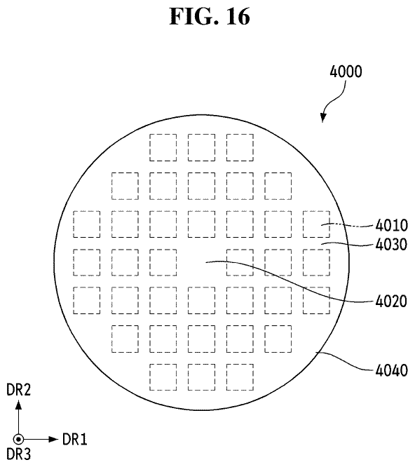

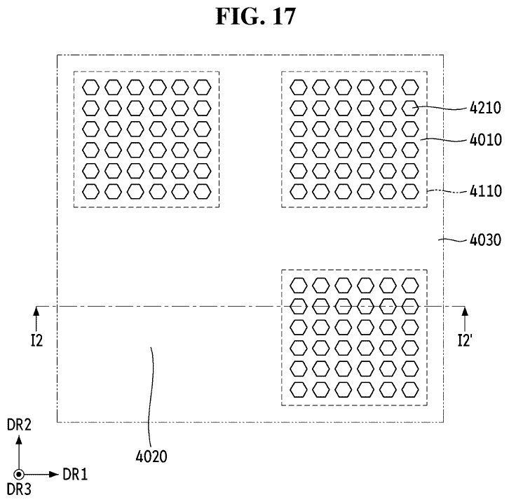

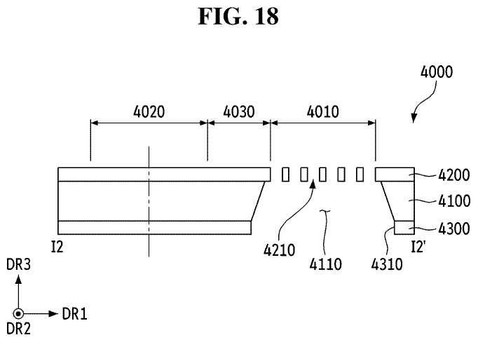

FIG. 16 is a schematic plan view illustrating an example of the deposition mask illustrated in FIG. 14. FIG. 17 is a schematic enlarged plan view illustrating mask cell regions and a closed cell region illustrated in FIG. 16, and FIG. 18 is a schematic enlarged cross-sectional view taken along line I2-I2′ illustrated in FIG. 17.

Referring to FIGS. 16 to 18, a deposition mask 4000 may include mask cell regions 4010 respectively corresponding to the display cell regions 3010 of the backplane substrate 3000, and a closed cell region 4020 corresponding to the non-display cell region 3020 of the backplane substrate 3000. Further, the deposition mask 4000 may include a grid region 4030 disposed between the mask cell regions 4010 and the closed cell region 4020.

The mask cell regions 4010 and the closed cell region 4020 may be arranged in a matrix form along the first direction DR1 and the second direction DR2, as illustrated in FIG. 16. In particular, the mask cell regions 4010 and the closed cell region 4020 may be arranged to correspond to the display cell regions 3010 and the non-display cell region 3020 of the backplane substrate 3000, respectively. In this case, the closed cell region 4020 may be disposed at the central portion of the deposition mask 4000. For example, the first direction DR1 may be the first horizontal direction, and the second direction DR2 may be the second horizontal direction perpendicular to the first direction DR1. In this case, the first direction DR1 may be the X-axis direction, and the second direction DR2 may be the Y-axis direction.

The deposition mask 4000 may include a mask frame 4100, a membrane 4200 disposed on the front surface of the mask frame 4100, and a rear inorganic film 4300 disposed on the rear surface of the mask frame 4100. Each of the mask cell regions 4010 may have a plurality of pixel openings 4210 exposing the electrode patterns AND of the backplane substrate 3000 in a deposition process, and the plurality of pixel openings 4210 may be formed to penetrate the membrane 4200. The mask frame 4100 may have cell openings 4110 exposing the plurality of pixel openings 4210, and the cell openings 4110 may be formed to penetrate the mask frame 4100. The rear inorganic film 4300 may have rear openings 4310 exposing the cell openings 4110, and the rear openings 4310 may be formed to penetrate the rear inorganic film 4300. That is, each of the mask cell regions 4010 may include the plurality of pixel openings 4210, the cell opening 4110, and the rear opening 4310.

For example, the membrane 4200 and the rear inorganic film 4300 may be formed of an inorganic material such as, for example, silicon nitride (SiNx), and may be formed to have a thickness of about 0.5 μm to about 3 μm by a thermal chemical vapor deposition (TCVD) process. That is, the front inorganic film and the rear inorganic film 4300 may be simultaneously formed on the front surface and the rear surface of the mask frame 4100 by the TCVD process, respectively, and the front inorganic film may be used as the membrane 4200.

A single crystal silicon substrate may be used as the mask frame 4100, and the pixel openings 4210 may be formed by forming the membrane 4200 on the front surface of the mask frame 4100 and then patterning the membrane 4200. For example, the pixel openings 4210 may be formed by forming a photoresist pattern (not illustrated) that exposes portions where the pixel openings 4210 are to be formed on the membrane 4200, and then performing an anisotropic etching process using the photoresist pattern as an etching mask until the front surface of the mask frame 4100 is exposed. At this time, the pixel openings 4210 may not be formed in the closed cell region 4020.

The rear openings 4310 may be formed by forming the rear inorganic film 4300 on the rear surface of the mask frame 4100 and then patterning the rear inorganic film 4300. For example, the rear openings 4310 may be formed by forming a photoresist pattern (not illustrated) that exposes portions where the rear openings 4310 are to be formed on the rear inorganic film 4300, and then performing an anisotropic etching process using the photoresist pattern as an etching mask until the rear surface of the mask frame 4100 is exposed. At this time, the rear openings 4310 may not be formed in the closed cell region 4020.

The cell openings 4110 may be formed to expose the pixel openings 4210 of the membrane 4200 through an anisotropic etching process using the rear inorganic film 4300 as an etching mask. For example, the cell openings 4110 may be formed through a wet etching process using tetramethylammonium hydroxide (TMAH) or potassium hydroxide (KOH). In this case, the <100> crystal direction of the single crystal silicon substrate used as the mask frame 4100 may be the third direction DR3, such that the cell openings 4110 may be formed to have a width that gradually decreases toward the membrane 4200, i.e., in the third direction DR3, by the wet etching process. In this case, the third direction DR3 may be a Z-axis direction. For example, each of the inner surfaces of the cell openings 4110 may be formed to have an inclination of about 54.74°. At this time, the cell openings 4110 may not be formed in the closed cell region 4020.

Referring back to FIG. 14, the deposition apparatus 2000 according to an embodiment of the present disclosure may include the deposition source 2200 for providing a deposition material on the backplane substrate 3000, a substrate chuck 2300 for supporting the backplane substrate 3000 such that the backplane substrate 3000 faces the deposition source 2200, and a mask stage 5000 which is disposed between the deposition source 2200 and the substrate chuck 2300 and supports the deposition mask 4000 such that the deposition mask 4000 faces the backplane substrate 3000.

The deposition source 2200, the substrate chuck 2300, and the mask stage 5000 may be disposed in a process chamber 2100. The process chamber 2100 may have an internal space, and a deposition process for forming a deposition material layer on the backplane substrate 3000 may be performed in the internal space of the process chamber 2100. The process chamber 2100 may be connected to a vacuum pump (not illustrated), and a vacuum atmosphere may be created in the internal space of the process chamber 2100 by the vacuum pump. An opening (not illustrated) for loading/unloading of the backplane substrate 3000 and the deposition mask 4000 may be provided on one wall of the process chamber 2100, and the opening may be opened and closed by a gate valve (not illustrated).

The deposition source 2200 may be disposed in the process chamber 2100, and a deposition material may be stored in the deposition source 2200. The deposition source 2200 may evaporate a deposition material such as, for example, an organic material, an inorganic material, a conductive material, or the like, and the evaporated deposition material may be deposited on the electrode patterns AND of the backplane substrate 3000 through the pixel openings 4210 of the deposition mask 4000. For example, the deposition source 2200 may evaporate an organic material for forming light emitting material layers on the backplane substrate 3000, and may be provided with a heater (not illustrated) for evaporating the organic material. The evaporated deposition material may be deposited on the electrode patterns AND of the backplane substrate 3000 through the pixel openings 4210 of the deposition mask 4000. As illustrated in FIG. 14, the deposition source 2200 may be disposed on the central portion of the bottom surface of the process chamber 2100, but the deposition source 2200 may be configured to move horizontally by a separate driver (not illustrated).

The substrate chuck 2300 may be disposed above the deposition source 2200 and may support the backplane substrate 3000 such that the backplane substrate 3000 faces the deposition source 2200, that is, such that the backplane substrate 3000 faces the deposition mask 4000. For example, the substrate chuck 2300 may be an electrostatic chuck that holds the rear surface of the backplane substrate 3000 using an electrostatic force. Specifically, the electrode patterns AND and the pixel defining film PDL may be disposed on the front surface of the backplane substrate 3000, and the substrate chuck 2300 may hold the rear surface of the backplane substrate 3000 such that the front surface of the backplane substrate 3000 faces the deposition source 2200.

A plurality of lift fingers 2500 for loading the backplane substrate 3000 onto the substrate chuck 2300 may be disposed in the process chamber 2100. The lift fingers 2500 may be disposed around the substrate chuck 2300 and the mask stage 5000, and may be respectively moved vertically by finger drivers 2510. For example, three or four lift fingers 2500 may be disposed around the substrate chuck 2300 and the mask stage 5000. The backplane substrate 3000 may be loaded into the process chamber 2100 by a transfer robot (not illustrated), and may be transferred from the transfer robot onto the lift fingers 2500 under the substrate chuck 2300. In this case, the rear surface of the backplane substrate 3000 may face the bottom surface of the substrate chuck 2300, and the lift fingers 2500 may support the front edge portions of the backplane substrate 3000. The finger drivers 2510 may raise the lift fingers 2500 such that the backplane substrate 3000 becomes adjacent to the bottom surface of the substrate chuck 2300 and, then, the rear surface of the backplane substrate 3000 may be held on the bottom surface of the substrate chuck 2300 by an electrostatic force.

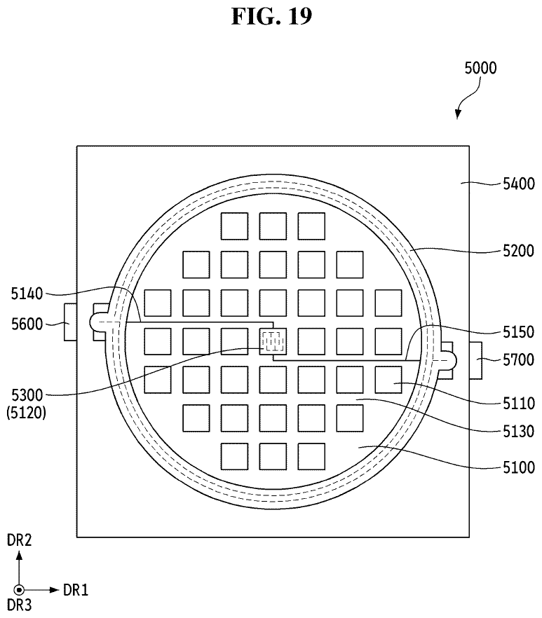

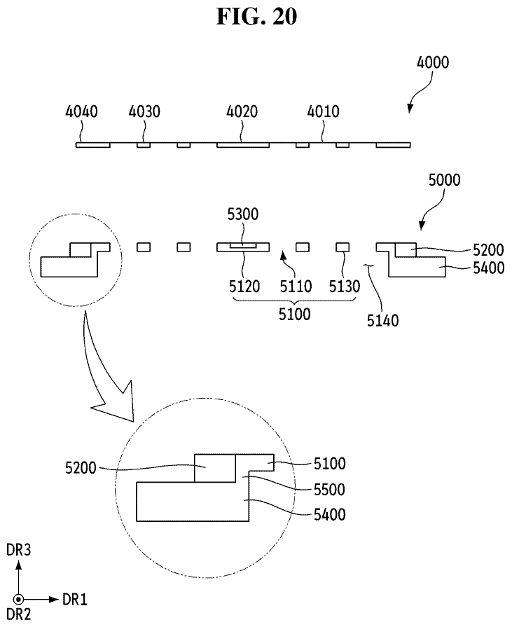

FIG. 19 is a schematic plan view illustrating the mask stage illustrated in FIG. 14. FIG. 20 is a schematic cross-sectional view illustrating the mask stage illustrated in FIG. 19.

Referring to FIGS. 19 and 20, the mask stage 5000 may include a lattice support 5100 for supporting the deposition mask 4000. For example, the lattice support 5100 may support the other region except the edge region 4040 of the deposition mask 4000. The mask stage 5000 may include a first electrostatic chuck 5200 for supporting the edge region 4040 of the deposition mask 4000. The first electrostatic chuck 5200 may hold the edge region 4040 of the deposition mask 4000 using a first electrostatic force. For example, the first electrostatic chuck 5200 may have a circular ring shape and may be disposed to surround the lattice support 5100.

The lattice support 5100 may support the mask cell regions 4010, the closed cell region 4020, and the grid region 4030 of the deposition mask 4000. For example, the lattice support 5100 may include a plurality of opening regions 5110 corresponding to the mask cell regions 4010, a chuck mount region 5120 corresponding to the closed cell region 4020, and a rib region 5130 disposed between the opening regions 5110 and the chuck mount region 5120. Specifically, when the deposition mask 4000 is placed on the lattice support 5100, the opening regions 5110 of the lattice support 5100 may be through openings exposing the mask cell regions 4010 of the deposition mask 4000, and the rib region 5130 of the lattice support 5100 may support the grid region 4030 of the deposition mask 4000.

The chuck mount region 5120 of the lattice support 5100 may be a closed region where no through opening is formed. In particular, when the deposition mask 4000 is placed on the lattice support 5100, the closed cell region 4020 of the deposition mask 4000 may be disposed on the chuck mount region 5120 of the lattice support 5100, and a second electrostatic chuck 5300 may be disposed on the chuck mount region 5120. The second electrostatic chuck 5300 may support a portion of the deposition mask 4000, for example, the closed cell region 4020 of the deposition mask 4000, and may hold the closed cell region 4020 of the deposition mask 4000 using a second electrostatic force.

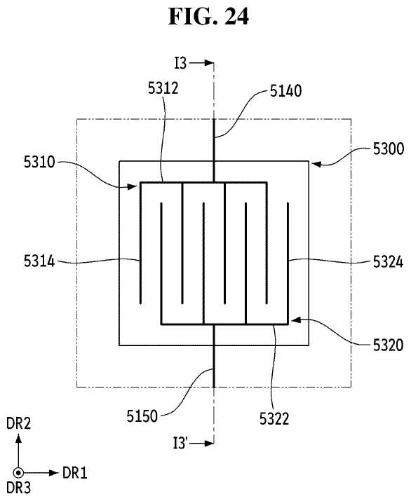

For example, the chuck mount region 5120 may have a recess 5122 (see FIG. 24) into which the second electrostatic chuck 5300 is inserted, and the second electrostatic chuck 5300 may be disposed on the bottom surface of the recess 5122. In particular, the top surface of the second electrostatic chuck 5300 may have the same height as the top surface of the rib region 5130 such that the top surface of the second electrostatic chuck 5300 and the top surface of the rib region 5130 flatly support the deposition mask 4000. Further, the top surface of the first electrostatic chuck 5200, the top surface of the rib region 5130, and the top surface of the second electrostatic chuck 5300 may all be arranged such that the top surfaces have the same height as one another.

The mask stage 5000 may include a base plate 5400 disposed under the lattice support 5100 and a support ring 5500 disposed between the lattice support 5100 and the base plate 5400. The base plate 5400 may have an opening 5410 exposing the lattice support 5100, and the support ring 5500 may be disposed between the outer edge portion of the lattice support 5100 and the inner edge portion of the base plate 5400. In this case, the first electrostatic chuck 5200 may be disposed on the base plate 5400 to surround the lattice support 5100. As illustrated, the base plate 5400 has a quadrilateral plate shape, but, unlike that, the base plate 5400 may have a disc shape. In some aspects, the base plate 5400, the lattice support 5100, and the support ring 5500 may be integrally formed. In some aspects, the base plate 5400, the lattice support 5100, and the support ring 5500 may be separate components.

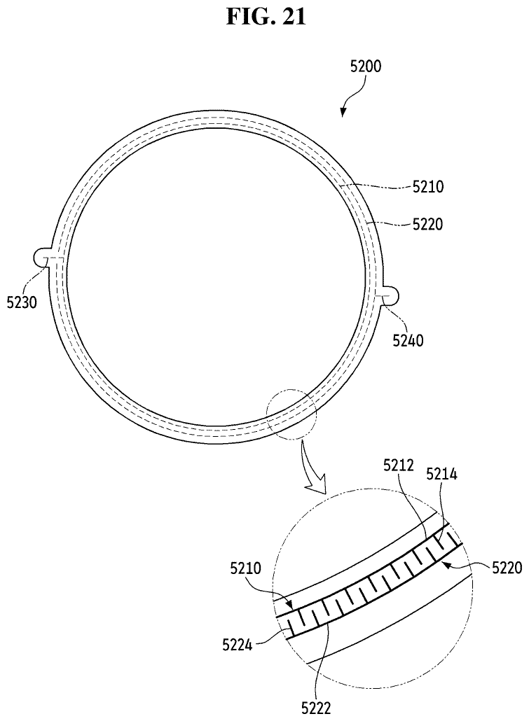

FIG. 21 is a schematic plan view illustrating the first electrostatic chuck illustrated in FIG. 19.

Referring to FIG. 21, the first electrostatic chuck 5200 may provide a first electrostatic force for holding the edge region 4040 of the deposition mask 4000. For example, the first electrostatic chuck 5200 may include a first electrostatic electrode 5210 and a second electrostatic electrode 5220 for generating the first electrostatic force. A first electrostatic voltage may be applied to the first electrostatic electrode 5210, and a second electrostatic voltage different from the first electrostatic voltage may be applied to the second electrostatic electrode 5220. For example, a positive voltage may be applied to the first electrostatic electrode 5210, and a negative voltage may be applied to the second electrostatic electrode 5220. In this case, the first electrostatic chuck 5200 may include a first connection line 5230 for applying a first electrostatic voltage to the first electrostatic electrode 5210 and a second connection line 5240 for applying a second electrostatic voltage to the second electrostatic electrode 5220.

The first electrostatic chuck 5200 may be formed of a ceramic material such as, for example, aluminum oxide (AlOx), aluminum nitride (AlN), yttrium oxide (YOx), or the like, and may be manufactured by a pressure sintering process, for example. The first electrostatic electrode 5210, the second electrostatic electrode 5220, the first connection line 5230, and the second connection line 5240 may be formed of a metal material such as, for example, tungsten (W), molybdenum (Mo), titanium (Ti), or the like, and may be formed by a pressure sintering process, for example. For example, the first electrostatic electrode 5210 may include a first main electrode 5212 having a circular ring shape and a plurality of first branch electrodes 5214 extending from the first main electrode 5212 toward the second electrostatic electrode 5220, and the second electrostatic electrode 5220 may include a second main electrode 5222 having a circular ring shape and disposed inside the first main electrode 5212 and a plurality of second branch electrodes 5224 extending from the second main electrode 5222 toward the first electrostatic electrode 5210. In this case, the first branch electrodes 5214 and the second branch electrodes 5224 may be alternately arranged in a circumferential direction.

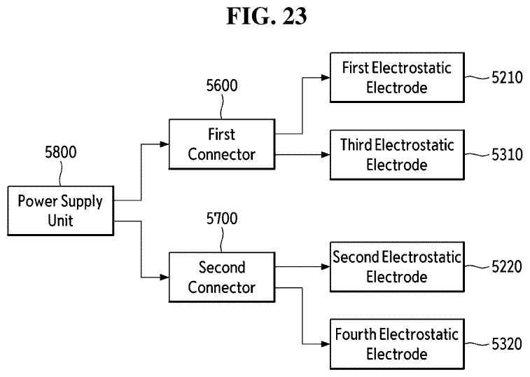

Referring back to FIG. 19, the mask stage 5000 may include a first connector 5600 and a second connector 5700 for connecting the first electrostatic electrode 5210 and the second electrostatic electrode 5220 to a power supply unit 5800 (see FIG. 23).

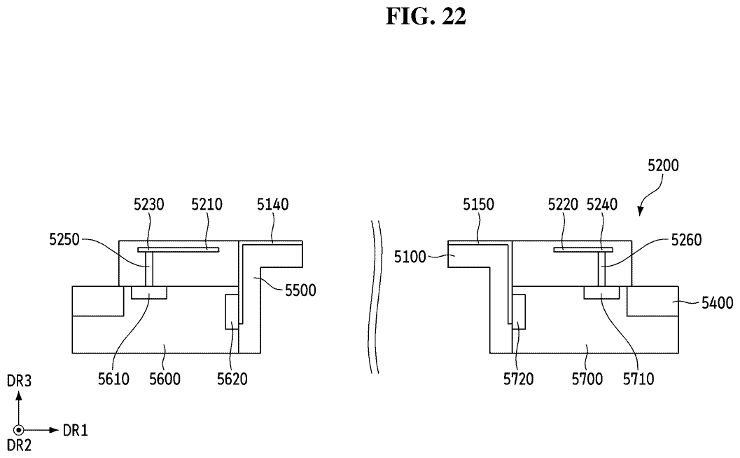

FIG. 22 is a schematic enlarged cross-sectional view illustrating the first connector and the second connector illustrated in FIG. 19. FIG. 23 is a block diagram illustrating the first connector and the second connector illustrated in FIG. 19.

Referring to FIGS. 22 and 23, the deposition apparatus 2000 may include the power supply unit 5800 for applying a first electrostatic voltage and a second electrostatic voltage to the first electrostatic electrode 5210 and the second electrostatic electrode 5220, respectively. The first connector 5600 may connect the power supply unit 5800 to the first electrostatic electrode 5210, and the second connector 5700 may connect the power supply unit 5800 to the second electrostatic electrode 5220. The first connector 5600 and the second connector 5700 may be mounted in the base plate 5400. For example, the first connector 5600 and the second connector 5700 may include a first contact pad 5610 and a second contact pad 5710, respectively, and the first electrostatic chuck 5200 may include a first contact plug 5250 for connecting the first connection line 5230 and the first contact pad 5610 and a second contact plug 5260 for connecting the second connection line 5240 and the second contact pad 5710. In this case, the first connector 5600 and the second connector 5700 may be mounted at the base plate 5400 such that the first contact pad 5610 and the second contact pad 5710 are exposed through the top surface of the base plate 5400, and the first electrostatic chuck 5200 may be disposed on the base plate 5400 such that the first contact plug 5250 and the second contact plug 5260 are positioned on the first contact pad 5610 and the second contact pad 5710, respectively.

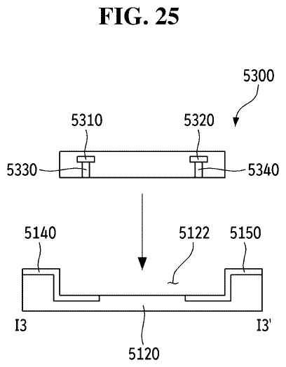

FIG. 24 is a schematic enlarged plan view illustrating the second electrostatic chuck illustrated in FIG. 19, and FIG. 25 is a schematic enlarged cross-sectional view taken along line I3-I3′ illustrated in FIG. 24.

Referring to FIGS. 24 and 25, the chuck mount region 5120 may be provided with the recess 5122 into which the second electrostatic chuck 5300 is inserted. The second electrostatic chuck 5300 may support the closed cell region 4020 of the deposition mask 4000, and may hold the closed cell region 4020 of the deposition mask 4000 using a second electrostatic force. For example, the second electrostatic chuck 5300 may include a third electrostatic electrode 5310 and a fourth electrostatic electrode 5320 for generating a second electrostatic force. A third electrostatic voltage may be applied to the third electrostatic electrode 5310, and a fourth electrostatic voltage different from the third electrostatic voltage may be applied to the fourth electrostatic electrode 5320. For example, a positive voltage may be applied to the third electrostatic electrode 5310, and a negative voltage may be applied to the fourth electrostatic electrode 5320.

The second electrostatic chuck 5300 may be formed of a ceramic material such as, for example, aluminum oxide (AlOx), aluminum nitride (AlN), yttrium oxide (YOx), or the like, and may be manufactured by a pressure sintering process, for example. The third electrostatic electrode 5310 and the fourth electrostatic electrode 5320 may be formed of a metal material such as, for example, tungsten (W), molybdenum (Mo), titanium (Ti), or the like, and may be formed by a pressure sintering process, for example. For example, the third electrostatic electrode 5310 may include a third main electrode 5312 extending in the first direction DR1 and a plurality of third branch electrodes 5314 extending from the third main electrode 5312 toward the fourth electrostatic electrode 5320, and the fourth electrostatic electrode 5320 may include a fourth main electrode 5322 extending parallel to the third main electrode 5312 and a plurality of fourth branch electrodes 5324 extending from the fourth main electrode 5322 toward the third electrostatic electrode 5310. In this case, the third branch electrodes 5314 and the fourth branch electrodes 5324 may extend in the second direction DR2 intersecting the first direction DR1, and may be alternately arranged in the first direction DR1.

The second electrostatic chuck 5300 may be inserted into the recess 5122 of the chuck mount region 5120. In particular, the second electrostatic chuck 5300 may be disposed on the bottom surface of the recess 5122, and a third connection line 5140 for applying a third electrostatic voltage to the third electrostatic electrode 5310 and a third connection line 5150 for applying a fourth electrostatic voltage to the fourth electrostatic electrode 5320 may be disposed on the bottom surface of the recess 5122. For example, the third connection line 5140 and the third connection line 5150 may be disposed on the bottom surface and the inner surface of the recess 5122, as illustrated in FIG. 25, and may extend in a radial direction on the lattice support 5100, as illustrated in FIG. 19. In this case, the second electrostatic chuck 5300 may include a third contact plug 5330 for connecting the third electrostatic electrode 5310 and the third connection line 5140 and a fourth contact plug 5340 for connecting the fourth electrostatic electrode 5320 and the fourth connection line 5150.

Referring back to FIGS. 22 and 23, the power supply unit 5800 may apply a third electrostatic voltage and a fourth electrostatic voltage to the third electrostatic electrode 5310 and the fourth electrostatic electrode 5320, respectively. The first connector 5600 may connect the power supply unit 5800 to the third electrostatic electrode 5310, and the second connector 5700 may connect the power supply unit 5800 to the fourth electrostatic electrode 5320. The first connector 5600 and the second connector 5700 may include a third contact pad 5620 and a fourth contact pad 5720, respectively. The third connection line 5140 and the fourth connection line 5150 may extend downward on the outer surface of the lattice support 5100 and the outer surface of the support ring 5500, and may be connected to the third contact pad 5620 of the first connector 5600 and the fourth contact pad 5720 of the second connector 5700, respectively, as illustrated in FIG. 22. However, the method of connecting the first electrostatic electrode 5210 and the third electrostatic electrode 5310 to the first connector 5600 and the method of connecting the second electrostatic electrode 5220 and the fourth electrostatic electrode 5320 to the second connector 5700 may be variously changed, such that the scope of the present disclosure may not be limited by the methods described herein.

According to one embodiment of the present disclosure, the lattice support 5100 may be formed of a nickel-iron alloy such as, for example, invar, a precipitation hardening stainless steel such as, for example, STS 630 or STS 631, a ceramic material such as, for example, aluminum oxide (AlOx), aluminum nitride (AlN), or yttrium oxide (YOx), or the like. The third connection line 5140 and the fourth connection line 5150 may be formed using conductive ink containing a conductive material such as, for example, silver, copper, graphene, or the like. For example, the third connection line 5140 and the fourth connection line 5150 may be formed by an inkjet printing process. In some embodiments, although not illustrated, when the lattice support 5100 is formed of a nickel-iron alloy or stainless steel, the lattice support 5100 may further include an insulating coating layer (not illustrated) for electrically insulating the third and fourth connection lines 5140 and 5150. For example, the insulating coating layer may include aluminum oxide (AlOx), and may be formed by an atomic layer deposition process.

Referring back to FIG. 14, the deposition mask 4000 may be loaded into the process chamber 2100 by the transfer robot, and may be transferred onto the lift fingers 2500 above the mask stage 5000. The edge portions of the deposition mask 4000 may be placed on the ends of the lift fingers 2500, and the finger drivers 2510 may lower the lift fingers 2500 to load the deposition mask 4000 onto the mask stage 5000. In this case, although not illustrated, recesses (not illustrated) into which the lift fingers 2500 are inserted may be provided at the edge portions of the top surface of the first electrostatic chuck 5200, and the finger drivers 2510 may rotate the lift fingers 2500 such that the lift fingers 2500 do not overlap the mask stage 5000 after the deposition mask 4000 is loaded on the mask stage 5000.

The deposition apparatus 2000 may include a substrate chuck driver 2600 for moving the substrate chuck 2300 and a stage driver 2700 for moving the mask stage 5000. For example, the substrate chuck driver 2600 may move the substrate chuck 2300 in the first direction DR1, the second direction DR2, and the third direction DR3 to adjust the position of the backplane substrate 3000. In this case, the first direction DR1 may be the first horizontal direction, the second direction DR2 may be the second horizontal direction perpendicular to the first direction DR1, and the third direction DR3 may be the vertical direction. That is, the first direction DR1, the second direction DR2, and the third direction DR3 may be the X-axis direction, the Y-axis direction, and the Z-axis direction, respectively.

The substrate chuck driver 2600 may rotate the substrate chuck 2300 around the Z-axis in order to adjust the azimuth of the backplane substrate 3000. Further, the substrate chuck driver 2600 may rotate the substrate chuck 2300 around the X-axis, and may rotate the substrate chuck 2300 around the Y-axis in order to adjust the inclination of the backplane substrate 3000. For example, the substrate chuck driver 2600 may include a hexapod actuator 2610 that provides a motion of six degrees of freedom (X, Y, Z, θx, θy, and θz).

The substrate chuck driver 2600 may include a movable plate 2620 (also referred to herein as a substrate stage) to which the hexapod actuator 2610 is mounted, and a second actuator 2630 connected to the movable plate 2620. The movable plate 2620 may be disposed horizontally in the process chamber 2100, and the second actuator 2630 may be disposed above the process chamber 2100. The second actuator 2630 may be connected to the movable plate 2620 by a plurality of driving shafts 2632 extending in the third direction DR3, i.e., the vertical direction (Z-axis direction) through the upper lid of the process chamber 2100, and may move the movable plate 2620 in the central axis direction of the hexapod actuator 2610, i.e., the vertical direction. For example, the second actuator 2630 may be configured using a brushless DC motor, a linear motor, a direct drive (DD) motor, or the like, and may adjust the height of the substrate chuck 2300 for loading or unloading the backplane substrate 3000.

Although not illustrated in detail, the hexapod actuator 2610 may include a first platform connected to the substrate chuck 2300, a second platform mounted to the movable plate 2620, and six sub-actuators disposed between the first platform and the second platform. The six sub-actuators may move and rotate the first platform to adjust the horizontal position of the backplane substrate 3000, the vertical position of the backplane substrate 3000, the azimuth of the backplane substrate 3000, and the inclination of the backplane substrate 3000. For example, the six sub-actuators may each be configured using a brushless DC motor, a voice coil linear motor, a step motor, a direct drive (DD) motor, a servo motor, or the like.

The stage driver 2700 may move and rotate the mask stage 5000 to adjust the horizontal position of the deposition mask 4000 and the azimuth of the deposition mask 4000. The stage driver 2700 may move the mask stage 5000 in a direction parallel to the deposition mask 4000 and rotate the mask stage 5000 with respect to the central axis of the mask stage 5000. For example, the stage driver 2700 may move the mask stage 5000 in the first direction DR1 (X-axis) and the second direction DR2 (Y-axis), and may rotate the mask stage 5000 with respect to the third direction DR3 (Z-axis).

The stage driver 2700 may include, e.g., a piezo actuator 2710 that provides a motion of three degrees of freedom (X, Y, and Oz). The piezo actuator 2710 may have a circular ring or quadrilateral ring shape, and the mask stage 5000 may be disposed on the piezo actuator 2710. The stage driver 2700 may include a support plate 2720 that is horizontally disposed in the process chamber 2100 and supports the piezo actuator 2710. For example, the support plate 2720 may have an opening for exposing the deposition mask 4000 toward the deposition source 2200, and may be supported by a plurality of posts 2722 connected to the upper lid of the process chamber 2100. Since, however, the support structure of the support plate 2720 may be variously changed, the scope of the present disclosure is not be limited thereby.

According to one embodiment of the present disclosure, after the deposition mask 4000 is loaded on the mask stage 5000, the first electrostatic chuck 5200 and the second electrostatic chuck 5300 may hold the deposition mask 4000 using the first electrostatic force and the second electrostatic force, respectively. As a result, the deposition mask 4000 may be sufficiently closely attached to the mask stage 5000, such that the warpage of the deposition mask 4000 may be reduced. For example, the first electrostatic chuck 5200 and the second electrostatic chuck 5300 may simultaneously hold the edge region 4040 and the closed cell region 4020 of the deposition mask 4000. In another example, the first electrostatic chuck 5200 and the second electrostatic chuck 5300 may sequentially hold the edge region 4040 and the closed cell region 4020 of the deposition mask 4000. For still another example, the second electrostatic chuck 5300 and the first electrostatic chuck 5200 may sequentially hold the closed cell region 4020 and the edge region 4040 of the deposition mask 4000.

After the backplane substrate 3000 and the deposition mask 4000 are loaded on the substrate chuck 2300 and the mask stage 5000, the second actuator 2630 may lower the substrate chuck 2300 to a preset height, and the hexapod actuator 2610 may adjust the inclination of the substrate chuck 2300 to adjust the parallelism between the substrate chuck 2300 and the mask stage 5000. For example, although not illustrated, a plurality of gap sensors (not illustrated) for measuring the gap between the substrate chuck 2300 and the first electrostatic chuck 5200 may be mounted at the substrate chuck 2300, and the hexapod actuator 2610 may adjust the parallelism between the substrate chuck 2300 and the mask stage 5000 based on the measured values of the gap sensors.

Further, the hexapod actuator 2610 or the piezo actuator 2710 may perform alignment between the backplane substrate 3000 and the deposition mask 4000. For example, although not illustrated, a plurality of substrate alignment keys (not illustrated) may be arranged on the edge portions of the backplane substrate 3000, and a plurality of mask alignment keys (not illustrated) corresponding to the plurality of substrate alignment keys may be arranged on the edge portions of the deposition mask 4000. The deposition apparatus 2000 may include a camera unit (not illustrated) for detecting the substrate alignment key and the mask alignment key, and an illumination unit (not illustrated) for illuminating the substrate alignment key and the mask alignment key, and the substrate chuck 2300 and/or the mask stage 5000 may be provided with a through hole (not illustrated) for providing illumination light and detecting the substrate alignment key and the mask alignment key.

For example, the illumination unit may provide near infrared (NIR) or short wave infrared (SWIR) light, e.g., infrared light having a wavelength of about 1010 nm to about 1020 nm, and the camera unit may detect infrared light transmitted through the backplane substrate 3000 and the deposition mask 4000. The hexapod actuator 2610 or the piezo actuator 2710 may perform alignment between the backplane substrate 3000 and the deposition mask 4000 based on positional information of the substrate alignment key and the mask alignment key acquired by the camera unit.

As described herein, after the parallelism adjustment between the substrate chuck 2300 and the mask stage 5000 and the alignment between the backplane substrate 3000 and the deposition mask 4000 are performed, the backplane substrate 3000 may be positioned on the deposition mask 4000. For example, the hexapod actuator 2610 may adjust the height of the substrate chuck 2300 such that the gap between the backplane substrate 3000 and the deposition mask 4000 becomes a preset gap, e.g., a gap of several μm. In another example, the hexapod actuator 2610 may adjust the height of the substrate chuck 2300 such that the backplane substrate 3000 is brought into contact with the deposition mask 4000.

After the backplane substrate 3000 is positioned on the deposition mask 4000, the deposition source 2200 may provide a deposition material onto the backplane substrate 3000 through the deposition mask 4000, thereby forming a deposition material layer on the backplane substrate 3000. For example, the deposition source 2200 may evaporate an organic material for forming light emitting material layers on the backplane substrate 3000, and the evaporated organic material may be deposited on the electrode patterns AND of the backplane substrate 3000 through the pixel openings 4210 of the deposition mask 4000.

According to one embodiment of the present disclosure, the edge region 4040 of the deposition mask 4000 may be held by the first electrostatic chuck 5200, and the closed cell region 4020 of the deposition mask 4000 may be held by the second electrostatic chuck 5300. Therefore, the warpage of the deposition mask 4000 may be reduced. As a result, the pixel position accuracy of the deposition material layers formed on the backplane substrate 3000 may be improved, and the color mixing phenomenon between the sub-pixels SP1, SP2, and SP3 may be reduced.

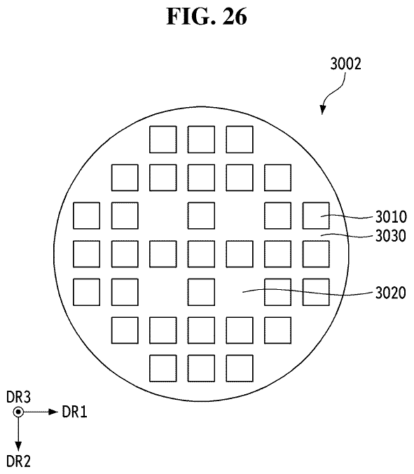

FIG. 26 is a schematic bottom view illustrating another example of the backplane substrate illustrated in FIG. 15.

Referring to FIG. 26, a backplane substrate 3002 may include a plurality of display cell regions 3010, a plurality of non-display cell regions 3020, and a scribe lane region 3030 disposed between the display cell regions 3010 and the non-display cell regions 3020. The display cell regions 3010 and the non-display cell regions 3020 may be arranged in a matrix form along the first direction DR1 and the second direction DR2. For example, the non-display cell regions 3020 may be arranged adjacent to the central portion of the backplane substrate 3002.

As illustrated in FIG. 26, the backplane substrate 3002 includes four non-display cell regions 3020, but the positions and number of the non-display cell regions 3020 may be variously changed, such that the scope of the present disclosure is not limited thereby. In some aspects, the backplane substrate 3002 is substantially the same as the backplane substrate 3000 described herein with reference to FIG. 15 except that the backplane substrate 3002 includes the plurality of non-display cell regions 3020, and repeated descriptions of like elements are omitted for brevity.

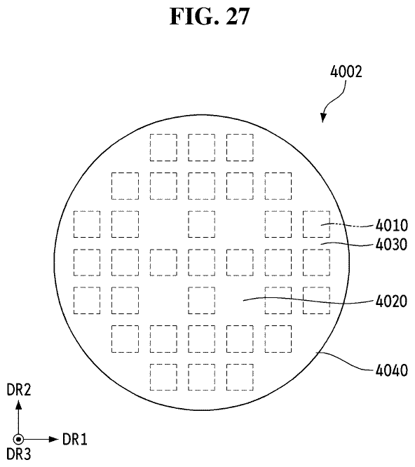

FIG. 27 is a schematic plan view illustrating another example of the deposition mask illustrated in FIG. 16.

Referring to FIG. 27, a deposition mask 4002 may include a plurality of mask cell regions 4010, a plurality of closed cell regions 4020, and a grid region 4030 disposed between the mask cell regions 4010 and the closed cell regions 4020. The mask cell regions 4010 and the closed cell regions 4020 may be arranged in a matrix form along the first direction DR1 and the second direction DR2. For example, the closed cell regions 4020 may be arranged adjacent to the central portion of the deposition mask 4002.

As illustrated in FIG. 27, the deposition mask 4002 includes four closed cell regions 4020, but the positions and number of the closed cell regions 4020 may be variously changed, such that the scope of the present disclosure is not limited thereby. In some aspects, the deposition mask 4002 is substantially the same as the deposition mask 4000 described herein with reference to FIGS. 16 to 18 except that the deposition mask 4002 includes the plurality of closed cell regions 4020, and repeated descriptions of like elements are omitted for brevity.

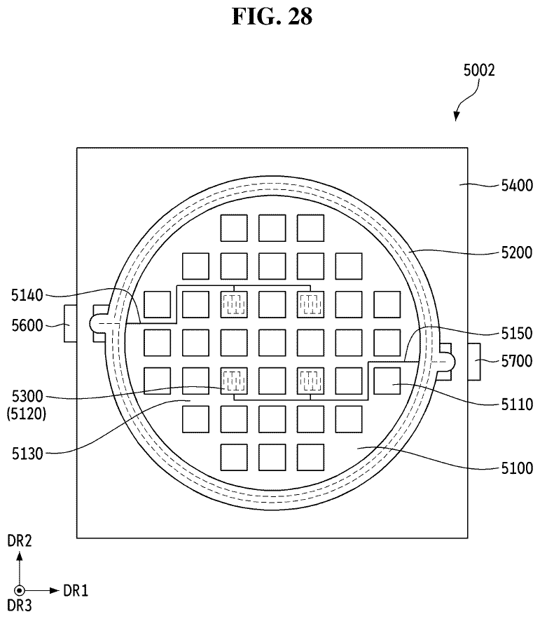

FIG. 28 is a schematic plan view illustrating another example of the mask stage illustrated in FIG. 19.

Referring to FIG. 28, a mask stage 5002 may include a lattice support 5100 for supporting the deposition mask 4002. For example, the lattice support 5100 may include a plurality of opening regions 5110 corresponding to the mask cell regions 4010, a plurality of chuck mount regions 5120 corresponding to the closed cell regions 4020, and a rib region 5130 that is disposed between the opening regions 5110 and the chuck mount regions 5120 and supports the grid region 4030. That is, the opening regions 5110 and the chuck mount regions 5120 may be arranged in a matrix form along the first direction DR1 and the second direction DR2, and the chuck mount regions 5120 may be arranged adjacent to the central portion of the lattice support 5100.

The mask stage 5002 may include a first electrostatic chuck 5200 that supports the edge region 4040 of the deposition mask 4002 and a plurality of second electrostatic chucks 5300 that support the closed cell regions 4020. The first electrostatic chuck 5200 may have a circular ring shape surrounding the lattice support 5100, and may hold the edge region 4040 of the deposition mask 4002 using a first electrostatic force. The second electrostatic chucks 5300 may be disposed on the chuck mount regions 5120, and may hold the closed cell regions 4020 of the deposition mask 4002 using a second electrostatic force. Each of the chuck mount regions 5120 may have a recess into which the second electrostatic chuck 5300 is inserted.

As illustrated in FIG. 28, the mask stage 5002 includes four chuck mount regions 5120 and four second electrostatic chucks 5300, but the positions and numbers of the chuck mount regions 5120 and the second electrostatic chucks 5300 may be variously changed, such that the scope of the present disclosure is not limited thereby. In some aspects, the mask stage 5002 is substantially the same as the mask stage 5000 described herein with reference to FIGS. 19 to 25, except that the mask stage 5002 includes the plurality of chuck mount regions 5120 and the plurality of second electrostatic chucks 5300, and repeated descriptions of like elements are omitted for brevity.

The invention should not be construed as being limited to the embodiments set forth herein. Rather, the example embodiments are provided such that this disclosure will be thorough and complete and will fully convey the concept of the invention to those skilled in the art.

While the invention has been particularly illustrated and described with reference to embodiments thereof, it will be understood by those of ordinary skill in the art that various changes in form and details may be made therein without departing from the spirit or scope of the invention as defined by the following claims.

What is claimed is:

1. A mask stage comprising:
a lattice support which supports a deposition mask and comprises a plurality of opening regions and at least one chuck mount region;
a first electrostatic chuck which surrounds the lattice support, supports an edge region of the deposition mask, and holds the edge region of the deposition mask using a first electrostatic force; and
at least one second electrostatic chuck which is disposed on the at least one chuck mount region, supports a portion of the deposition mask, and holds the portion of the deposition mask using a second electrostatic force.

2. The mask stage of claim 1, wherein:
the deposition mask comprises mask cell regions in which pixel openings are formed and a closed cell region in which pixel openings are not formed, and
the at least one second electrostatic chuck supports the closed cell region and holds the closed cell region using the second electrostatic force.

3. The mask stage of claim 1, wherein the at least one chuck mount region has a recess into which the at least one second electrostatic chuck is inserted.

4. The mask stage of claim 3, wherein:
the lattice support further comprises a grid region disposed between the plurality of opening regions and the at least one chuck mount region, and
a top surface of the grid region and a top surface of the at least one second electrostatic chuck are disposed at the same height.

5. The mask stage of claim 1, further comprising:
a base plate disposed under the lattice support and having an opening exposing the lattice support; and
a support ring disposed between the lattice support and the base plate.

6. The mask stage of claim 1, wherein:
the first electrostatic chuck comprises a first electrostatic electrode and a second electrostatic electrode,
the first electrostatic electrode comprises a first main electrode having a ring shape and a plurality of first branch electrodes extending from the first main electrode toward the second electrostatic electrode, and
the second electrostatic electrode comprises a second main electrode having a ring shape and a plurality of second branch electrodes extending from the second main electrode toward the first electrostatic electrode.

7. The mask stage of claim 6, further comprising:
a first connector connecting the first electrostatic electrode to a power supply unit; and
a second connector connecting the second electrostatic electrode to the power supply unit,
wherein the first electrostatic chuck further comprises:
a first connection line connecting the first electrostatic electrode and the first connector, and
a second connection line connecting the second electrostatic electrode and the second connector.

8. The mask stage of claim 1, wherein:
the at least one second electrostatic chuck comprises a third electrostatic electrode and a fourth electrostatic electrode,
the third electrostatic electrode comprises a third main electrode extending in a first direction and a plurality of third branch electrodes extending from the third main electrode toward the fourth electrostatic electrode, and
the fourth electrostatic electrode comprises a fourth main electrode extending parallel to the third main electrode and a plurality of fourth branch electrodes extending from the fourth main electrode toward the third electrostatic electrode.

9. The mask stage of claim 8, further comprising:
a first connector connecting the third electrostatic electrode to a power supply unit;
a second connector connecting the fourth electrostatic electrode to the power supply unit;
a third connection line disposed on the lattice support and connecting the third electrostatic electrode and the first connector; and
a fourth connection line disposed on the lattice support and connecting the fourth electrostatic electrode and the second connector.

10. The mask stage of claim 1, wherein:
the lattice support comprises a plurality of chuck mount regions, and
a plurality of second electrostatic chucks are respectively disposed on the plurality of chuck mount regions.

11. A deposition apparatus comprising:
a deposition source providing a deposition material onto a substrate;
a mask stage which is disposed above the deposition source and supports a deposition mask; and
a substrate chuck which is disposed above the mask stage and supports the substrate such that the substrate faces the deposition mask,
wherein the mask stage comprises:
a lattice support which supports the deposition mask and comprises a plurality of opening regions and at least one chuck mount region;
a first electrostatic chuck which surrounds the lattice support, supports an edge region of the deposition mask, and holds the edge region of the deposition mask using a first electrostatic force; and
at least one second electrostatic chuck which is disposed on the at least one chuck mount region, supports a portion of the deposition mask, and holds the portion of the deposition mask using a second electrostatic force.

12. The deposition apparatus of claim 11, wherein:
the deposition mask comprises mask cell regions in which pixel openings are formed and a closed cell region in which pixel openings are not formed, and
the at least one second electrostatic chuck supports the closed cell region and holds the closed cell region using the second electrostatic force.

13. The deposition apparatus of claim 11, wherein the at least one chuck mount region has a recess into which the at least one second electrostatic chuck is inserted.

14. The deposition apparatus of claim 13, wherein:
the lattice support further comprises a grid region disposed between the plurality of opening regions and the at least one chuck mount region, and
a top surface of the grid region and a top surface of the at least one second electrostatic chuck are disposed at the same height.

15. The deposition apparatus of claim 11, wherein the mask stage further comprises:
a base plate disposed under the lattice support and having an opening exposing the lattice support; and
a support ring disposed between the lattice support and the base plate.

16. The deposition apparatus of claim 11, wherein:
the first electrostatic chuck comprises a first electrostatic electrode and a second electrostatic electrode,
the first electrostatic electrode comprises a first main electrode having a ring shape and a plurality of first branch electrodes extending from the first main electrode toward the second electrostatic electrode, and
the second electrostatic electrode comprises a second main electrode having a ring shape and a plurality of second branch electrodes extending from the second main electrode toward the first electrostatic electrode.

17. The deposition apparatus of claim 16, wherein:
the mask stage further comprises:
a first connector connecting the first electrostatic electrode to a power supply unit; and
a second connector connecting the second electrostatic electrode to the power supply unit, and
the first electrostatic chuck further comprises:
a first connection line connecting the first electrostatic electrode and the first connector, and
a second connection line connecting the second electrostatic electrode and the second connector.

18. The deposition apparatus of claim 11, wherein the at least one second electrostatic chuck comprises a third electrostatic electrode and a fourth electrostatic electrode,
the third electrostatic electrode comprises a third main electrode extending in a first direction and a plurality of third branch electrodes extending from the third main electrode toward the fourth electrostatic electrode, and
the fourth electrostatic electrode comprises a fourth main electrode extending parallel to the third main electrode and a plurality of fourth branch electrodes extending from the fourth main electrode toward the third electrostatic electrode.

19. The deposition apparatus of claim 18, wherein the mask stage further comprises:
a first connector connecting the third electrostatic electrode to a power supply unit;
a second connector connecting the fourth electrostatic electrode to the power supply unit;
a third connection line disposed on the lattice support and connecting the third electrostatic electrode and the first connector; and
a fourth connection line disposed on the lattice support and connecting the fourth electrostatic electrode and the second connector.

20. An electronic device comprising:
a substrate; and
a plurality of light emitting material layers formed on the substrate by using a deposition apparatus,
wherein the deposition apparatus comprises:
a deposition source providing a deposition material onto the substrate;
a mask stage which is disposed above the deposition source and supports a deposition mask; and
a substrate chuck which is disposed above the mask stage and supports the substrate such that the substrate faces the deposition mask,
wherein the mask stage comprises:
a lattice support which supports the deposition mask and comprises a plurality of opening regions and at least one chuck mount region;
a first electrostatic chuck which surrounds the lattice support, supports an edge region of the deposition mask, and holds the edge region of the deposition mask using a first electrostatic force; and
at least one second electrostatic chuck which is disposed on the at least one chuck mount region, supports a portion of the deposition mask, and holds the portion of the deposition mask using a second electrostatic force.
